(19) United States
(12) Patent Application Publication
(10) Pub. No.: US 2026/0358269 A1
(43) Pub. Date: Nov. 12, 2026

(54) INSPECTION APPARATUS AND INSPECTION METHOD

(71) Applicant: KONICA MINOLTA, INC., Chiyoda-ku, Tokyo (JP)

(72) Inventors: Junichi JONO, Kita-ku, Tokyo (JP); Makoto TAKADA, Takatsuki-shi, Osaka (JP); Masaru FUSE, Ibaraki-shi, Osaka (JP); Saburou HIRAOKA, Tsukuba-shi, Ibaraki (JP)

(73) Assignee: KONICA MINOLTA, INC., Chiyoda-ku, Tokyo (JP)

(21) Appl. No.: 19/470,328

(22) PCT Filed: Mar. 8, 2024
(86) PCT No.: PCT/JP2024/008918

§ 371 Date: Sep. 29, 2025

(30) Foreign Application Priority Data
Mar. 31, 2023 (JP) 2023-056823

(51) Int. Cl. G01N 22/02

(52) U.S. Cl. CPC G01N 22/02

(57) ABSTRACT

An inspection apparatus includes a plurality of sensors that apply waves in different frequency bands to a target and that receive a transmitted wave and/or a reflected wave from the target, and a plurality of acquirers that are provided corresponding to the plurality of sensors and that acquire data and/or a feature amount at different depth positions or depth ranges of the target using different measurement conditions. The plurality of sensors or the plurality of sensors and the plurality of acquirers are formed in an integrated structure.

### TECHNICAL FIELD

The present invention relates to an inspection apparatus and an inspection method for nondestructively inspecting an inside of a structure.

### BACKGROUND ART

An inspection cost regarding deterioration and corrosion of an object buried in a large structure such as a reinforcing bar and a pipe in a bridge for a road and a railroad, in a building, and in the ground has become a social problem.

In recent years, for the purpose of reducing the inspection cost of the structure, for example, as in Patent Literature 1, a method has been proposed in which a sensor or a communication device is embedded in a structure in advance in order to detect a state inside the structure. However, the structure in which deterioration is a problem is basically the structure built several decades ago, and most of the structures have no sensor or the like buried therein in advance.

On the other hand, in a case where the state of the inside of the structure is precisely inspected, it is considered that an X-ray imaging apparatus or an elemental analysis (ion chromatography, EPMA, or the like) apparatus is used. However, it is necessary to use a large inspection apparatus that is not practical to handle on site. Furthermore, in elemental analysis and the like, microfracture of the structure is essential for collecting a sample for the inspection, and this operation may promote deterioration of the structure.

Representative examples of a measurement technique capable of inspection of the structure in a non-destructive manner include measurement techniques using radio waves (microwaves or terahertz waves), sound waves (hitting sound or ultrasound), light (infrared light, fluorescence, or Raman spectroscopy), and electricity (impedance). For example, Patent Literature 2 proposes a method of detecting a position of an object in the structure based on a reception time of a reflected wave from an object using a radio wave.

In addition, for detection of a moisture amount contained in the structure, it is general to use a technology for detecting electrical and chemical interactions due to a presence of water molecules. For example, Patent Literature 3 and Patent Literature 4 propose methods in which impedance characteristics are acquired under conditions of low salt concentration and the moisture amount is quantified using an approximation formula.

Furthermore, although elemental analysis is a method of directly detecting an ion contained in the structure, currently, a technique of indirectly estimating an influence of the ion from electrical characteristics is mainly used. For example. Patent Literature 5 proposes a method in which a database in which impedance characteristics and the water content and salt concentration of concrete are associated with each other is created in advance, and the salt concentration is specified from the impedance characteristics measured by a pair of electrodes disposed on a concrete surface. In addition, Patent Literature 6 proposes a method of characterizing a salt concentration from impedance characteristics measured by a pair of electrodes disposed on a concrete surface and a moisture amount and a water vapor amount separately measured by using a moisture percentage meter.

### CITATION LIST

### Patent Literature

Patent Literature 1: Japanese Unexamined Patent Publication No. 2008-134117
Patent Literature 2: Japanese Unexamined Patent Publication No. H1-282490
Patent Literature 3: U.S. Pat. No. 5,919,936
Patent Literature 4: U.S. Pat. No. 6,047,692
Patent Literature 5: Japanese Unexamined Patent Publication No. 2012-184948
Patent Literature 6: patent Ser. No. 06/338,238

### SUMMARY OF INVENTION

### Technical Problem

Conventionally, a measurement technology that can nondestructively perform inspection of a structure has been proposed. However, a measurement technique has not been established which separates factors of time-dependent degradation (degree of corrosion, ion content percentage, moisture percentage, and the like) while accurately grasping a position of an object inside the structure. In addition, since there are many demands for on-site immediate inspection, a measurement technology that is portable and can simply perform inspection of the inside of the structure in a non-destructive manner is required.

The present invention has been made in order to solve the above problem, and an object of the present invention is to provide an inspection apparatus and an inspection method capable of distinguishing deterioration factors such as the degree of corrosion, the ion content percentage, and the moisture percentage while accurately grasping the position of the object inside the structure.

### Solution to Problem

In order to solve the above-described problem, according to the present invention an inspection apparatus includes:
a plurality of sensors that apply waves in different frequency bands to a target and that receive a transmitted wave and/or a reflected wave from the target; and
a plurality of acquirers that are provided corresponding to the plurality of sensors and that acquire data and/or a feature amount at different depth positions or depth ranges of the target using different measurement conditions,
wherein the plurality of sensors or the plurality of sensors and the plurality of acquirers are formed in an integrated structure.

According to the present invention, an inspection method includes:
by using a plurality of sensors, applying waves in different frequency bands to a target and receiving a transmitted wave and/or a reflected wave from the target; and
with respect to reception signals from the plurality of sensors, acquiring data and/or a feature amount at different depth positions or depth ranges of the target using different measurement conditions.

According to the present invention, an inspection method includes:
when an inspection target is a structure formed of a reinforcing bar and concrete or a reinforcing bar and mortar,
acquiring by an impedance measurement method electrical impedance from 10 Hz to 10 MHz;
acquiring by a resonance measurement method dielectric constant of the concrete or the mortar based on a resonance frequency from 1 GHz to 10 GHz; and
estimating a moisture content and/or an ion content of the concrete or the mortar from the dielectric constant, and evaluating a corrosion state of the reinforcing bar in the structure by deriving conductivity of the reinforcing bar from the electrical impedance with a moisture content and/or an ion content as a correction value.

According to the present invention, an inspection method includes:
when an inspection target is a structure formed of a reinforcing bar and concrete or a reinforcing bar and mortar,
acquiring by an impedance measurement method electrical impedance from 10 Hz to 10 MHz; acquiring a reception signal from 1 GHz to 20 GHz by a time-of-flight measurement method or a Doppler method; and
deriving information on a position of the reinforcing bar in the structure and a moisture content and/or an ion content of concrete or mortar from the electrical impedance, and by using the reception signal, correcting the information on the position of the reinforcing bar and/or evaluating a corrosion state of the reinforcing bar.

### Advantageous Effects of Invention

According to the present invention, each deterioration factor can be isolated for measurement and inspection while a position of an object inside a structure is accurately grasped. Further, it is portable so that immediate inspection can be performed at the site, and the inspection of the inside of the structure can be performed easily.

### BRIEF DESCRIPTION OF DRAWINGS

FIG. 1A This is a diagram showing a front view illustrating an example of an inspection apparatus according to the present embodiment.

FIG. 1B This is a diagram showing a side view illustrating an example of the inspection apparatus according to the present embodiment.

FIG. 2 This is a diagram showing a block diagram illustrating an example of an inspection system according to the present embodiment.

FIG. 3 This is an explanatory diagram illustrating an example of an impedance measurement method.

FIG. 4A This is a diagram showing a graph showing an example of a relationship between an input alternating-current voltage and a response current.

FIG. 4B This is a diagram showing a graph illustrating an example of a complex representation of impedance.

FIG. 5A This is a diagram showing an explanatory diagram schematically illustrating a flow of a current in an impedance measurement method.

FIG. 5B This is a diagram showing another explanatory diagram schematically illustrating the flow of the current in the impedance measurement method.

FIG. 6 This is a diagram showing an explanatory diagram showing an example of a resonant circuit used in a resonance measurement method.

FIG. 7 This is a graph showing an example of a change in resonance frequency depending on a presence or absence of a derivative.

FIG. 8A This is a diagram showing an explanatory diagram showing a configuration for measuring a relationship between a presence or absence of a reinforcing bar and an impedance and resonance frequency.

FIG. 8B This is a graph showing the presence or absence of the reinforcing bar and a measurement result of the impedance.

FIG. 8C This is another graph showing the presence or absence of the reinforcing bar and the measurement result of the impedance.

FIG. 8D This is a graph showing the presence or absence of the reinforcing bar and a measurement result of a resonance frequency spectrum.

FIG. 9A This is a diagram showing an explanatory diagram illustrating a configuration for measuring a relation between a moisture content of the structure, and the impedance and resonance frequency.

FIG. 9B This is a graph illustrating a measurement result of the moisture content of the structure and the impedance.

FIG. 9C This is a graph illustrating the measurement result of the moisture content of the structure and the resonance frequency spectrum.

FIG. 10A This is a diagram showing an explanatory diagram showing a configuration for measuring the resonance frequency of polypropylene and concrete.

FIG. 10B This is a graph illustrating the measurement result of the resonance frequency spectrum of polypropylene and concrete.

FIG. 11A This is a diagram showing an explanatory diagram illustrating a configuration for measuring a relationship between a thickness of an insulating member and the resonance frequency.

FIG. 11B This is a graph showing the measurement result of the thickness of the insulating member and the resonance frequency spectrum.

FIG. 12A This is a flowchart illustrating an example of operation of the inspection apparatus and the inspection system according to the present embodiment.

FIG. 12B This is a flowchart illustrating another example of the operation of the inspection apparatus and the inspection system according to the present embodiment.

FIG. 12C This is a flowchart illustrating a detailed example of the operation of the inspection apparatus and the inspection system according to the present embodiment.

FIG. 13A This is a diagram showing a front view illustrating another example of the inspection apparatus according to the present embodiment.

FIG. 13B This is a diagram showing a side view illustrating another example of the inspection apparatus according to the present embodiment.

FIG. 14A This is a flowchart illustrating an example of an operation of the inspection apparatus and the inspection system according to another example of the present embodiment.

FIG. 14B This is a flowchart illustrating a detailed example of the operation of the inspection apparatus and the inspection system according to another example of the present embodiment.

FIG. 15A This is a diagram showing a front view showing still another example of the inspection apparatus according to the present embodiment.

FIG. 15B This is a diagram showing a front view showing still another example of the inspection apparatus according to the present embodiment.

FIG. 16A This is a diagram showing a front view illustrating an example of the inspection apparatus of the present embodiment applied to soil.

FIG. 16B This is a diagram showing a side view illustrating the example of the inspection apparatus of the present embodiment applied to the soil.

FIG. 17 This is a diagram showing a front view illustrating an example of the inspection apparatus of the present embodiment applied to a composite material or a functional film.

FIG. 18A This is a diagram showing a front view illustrating an example of the inspection apparatus of the present embodiment applied to meat.

FIG. 18B This is a diagram showing a front view illustrating an example of the inspection apparatus of the present embodiment applied to processed foods.

FIG. 19A This is a diagram showing a front view illustrating an example of the inspection apparatus of the present embodiment applied to a cereal product.

FIG. 19B This is a diagram showing a side view illustrating the example of the inspection apparatus of the present embodiment applied to the cereal product.

### DESCRIPTION OF EMBODIMENTS

In the following, an embodiment of an inspection apparatus and an inspection method of the present invention will be described with reference to the drawings.

### <Configuration Example of Inspection Apparatus of Present Embodiment>

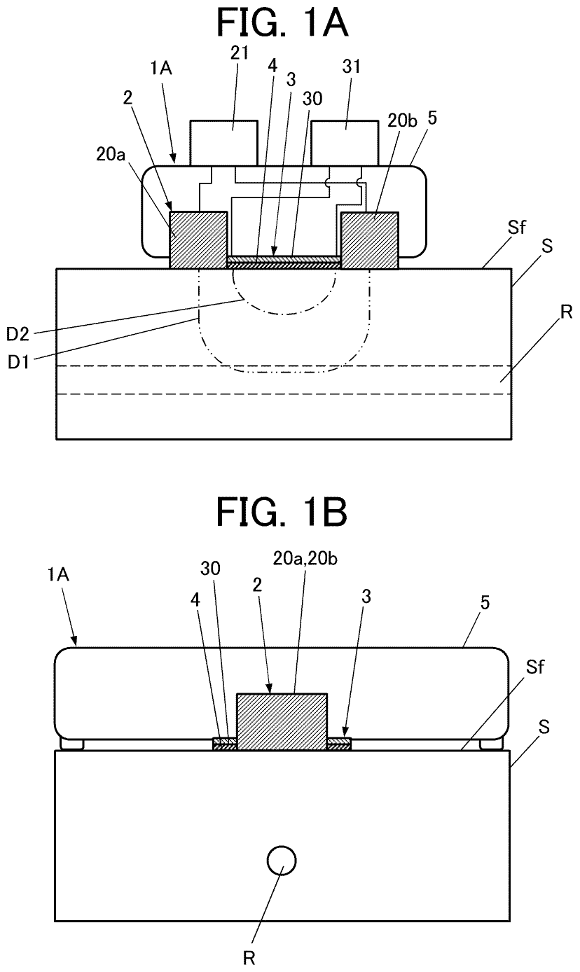

FIG. 1A is a front view illustrating an example of the inspection apparatus of the present embodiment, and FIG. 1B is a side view illustrating an example of the inspection apparatus of the present embodiment.

An inspection apparatus 1A acquires data used for a predetermined inspection from a concrete structure S in which a reinforcing bar R is arranged inside as an example of a target. The inspection apparatus 1A is installed on a surface Sf of the structure S. The surface Sf of the structure S is one surface of a plurality of surfaces constituting an outer surface of the structure S, and is a surface along an arrangement direction of the reinforcing bar R in the present example.

The inspection apparatus 1A includes a first sensor section 2 that applies waves in a first frequency band to the structure S and receives the waves transmitted through the structure S and/or the waves reflected by the structure S.

The first sensor section 2 includes an electrode 20a and an electrode 20b. When the inspection apparatus 1 is installed on the surface Sf of the structure S, the two electrodes 20a and 20b of the first sensor section 2 are in contact with the surface Sf of the structure S. In the first sensor section 2, the two electrodes 20a and 20b are arranged at a predetermined interval in a direction along the surface Sf of the structure S.

The first sensor section 2 applies, to the structure S, waves having frequencies within the range from 1 Hz to 100 MHz, for example, as the first frequency band.

The inspection apparatus 1A includes a first acquisition section 21 provided corresponding to the first sensor section 2. The first acquisition section 21 acquires data with a first resolution from a first range of the structure S under a first measurement condition with respect to a signal received from the first sensor section 2. Hereinafter, a measurement condition means a measurement method and/or a measurement parameter, and the measurement parameter includes a frequency band of a wave to be used. Note that the first acquisition section 21 is not illustrated in the side view of FIG. 1B.

The first acquisition section 21 uses an impedance measurement method as a first measurement condition. In addition, as an example of the first range, the first acquisition section 21 acquires data in which a depth position or a depth range from the surface Sf of the structure S is a first depth position or a first depth range. In the present example, the first acquisition section 21 acquires the data m a first depth range D1 between the electrode 20a and the electrode 20b. The first depth range D1 is a range in which the reinforcing bar R is included.

The inspection apparatus 1A includes a second sensor section 3 that applies the waves in a second frequency band to the structure S and receives the waves transmitted through the structure S and/or the waves reflected by the structure S.

The second sensor section 3 includes a resonant circuit 30. In the second sensor section 3, the resonant circuit 30 is provided between the electrode 20a and the electrode 20b.

The second sensor section 3 applies, to the structure S, waves having frequencies within the range from 1 GHz to 100 GHz, for example, as the second frequency band.

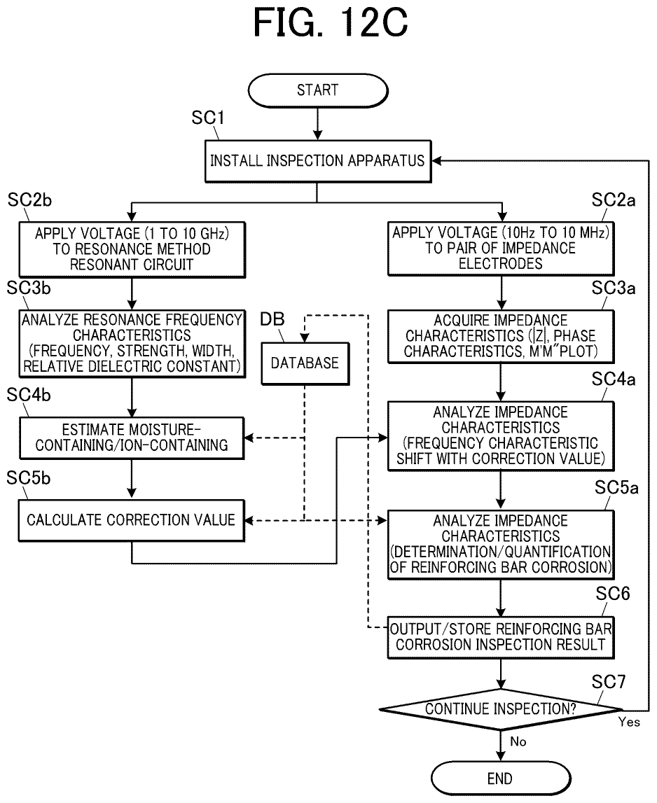

The inspection apparatus 1A includes a second acquisition section 31 provided corresponding to the second sensor section 3. The second acquisition section 31 acquires data with a second resolution from a second range of the structure S tinder a second measurement condition with respect to the signal received from the second sensor section 3. Note that the second acquisition section 31 is not illustrated in the side view of FIG. 11B.

The second acquisition section 31 uses a resonance measurement method using microwaves as the second measurement condition. In addition, as an example of the second range, the second acquisition section 31 acquires data in which the depth position or the depth range from the surface Sf of the structure S is a second depth position or a second depth range. The second acquisition section 31 acquires data in the second depth range D2 in the present example. The second depth range D2 is a range closer to the surface Sf than the depth at which the reinforcing bar R is arranged. Thus, the second range is a range smaller than the first range.

The inspection apparatus 1A includes an insulating member 4 between the electrode 20a and the electrode 20b. The insulating member 4 is an example of an interference reduction unit, and suppresses interference between the waves applied to the structure S by the first sensor section 2 and the second sensor section 3.

When the inspection apparatus 1 is installed on the surface Sf of the structure S, the insulating member 4 is disposed between the surface Sf of the structure S and the resonant circuit 30 between the two electrodes 20a and 20b.

Thus, when the wave is applied to the structure S by the first sensor section 2 and a reflected wave is transmitted to a predetermined depth, the insulating member 4 shields a path in which the reflected wave is received by the second sensor section 3. Therefore, the insulating member 4 mainly suppresses the interference to the second sensor section 3 by the wave applied to the structure S by the first sensor section 2.

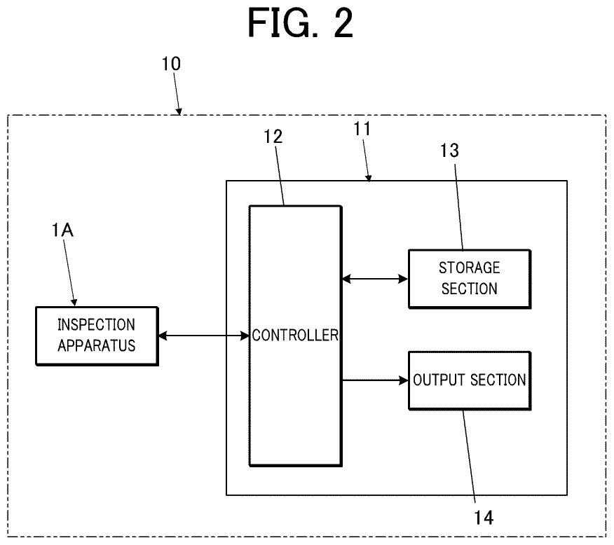

FIG. 2 is a block diagram illustrating an example of an inspection system according to the present embodiment. The inspection system 10 includes the above-described inspection apparatus 1A and an analysis apparatus 11. The analysis apparatus 11 includes a controller 12, a storage section 13, and an output section 14.

The controller 12 acquires first data or a first feature amount with a first resolution from a first range of the structure S. Further, the controller 12 acquires second data or a second feature amount with a second resolution higher than the first resolution from the second range smaller than the first range. Then, the controller 12 analyzes the first data or the first feature amount (hereinafter, also referred to as first data or the like) and the second data or the second feature amount (hereinafter, also referred to as second data or the like) by a predetermined method, and detects an internal structure, an internal state, and the like of the structure S. Here, the predetermined method is to analytically and/or statistically process the first data and the like and the second data and the like, and includes, for example, correcting the first data and the like with the second data and the like.

The storage section 13 stores a database or the like for analyzing the first data or the like and the second data or the like.

Note that the inspection apparatus 1A may be configured to further acquire third data and the like with a third resolution higher than the second resolution from a third range smaller than the second range. In this case, for example, the controller 12 corrects the first data and the like with the second and third data and the like (third data or third feature amount), and detects the internal structure, the internal state, and the like of the structure S. Alternatively, the controller 12 corrects the second data and the like with the third data and the like, corrects the first data and the like with the corrected second data and the like, and detects the internal structure, the internal state, and the like of the structure S. Hereinafter, the same applies to a case where the inspection apparatus 1A is configured to further acquire an n-th data and the like at an n-th resolution higher than an m-th resolution from an n-th range smaller than an m-th range.

### <Example of Measurement Conditions by Impedance Measurement Method and Resonance Measurement Method>

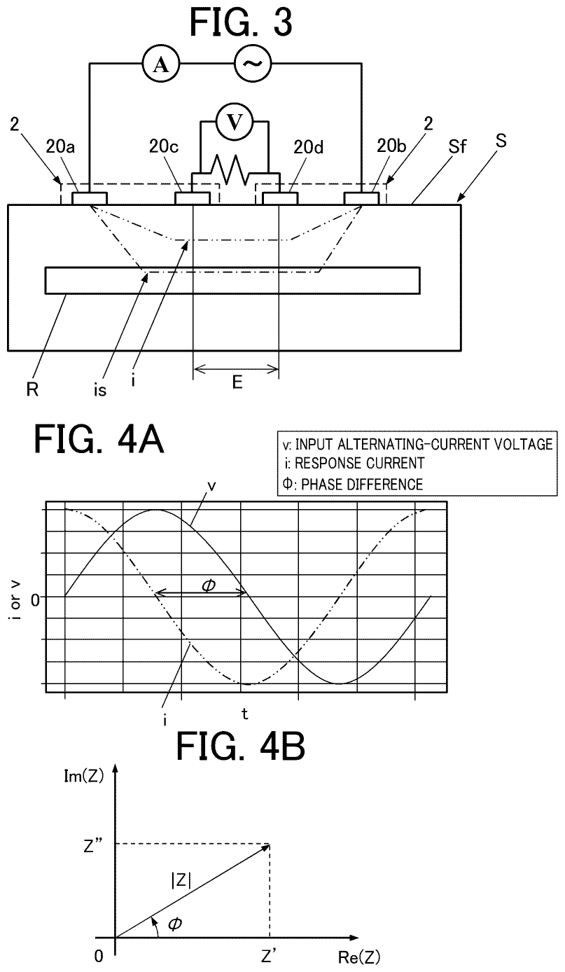

Next, measurement conditions used in the inspection apparatus 1A will be described. FIG. 3 is an explanatory diagram illustrating an example of an impedance measurement method. In the impedance measurement method, a pair of electrodes 20a and 20b are brought into contact with the surface Sf of the structure S, and a response current i (is) to an input alternating-current voltage v applied to the electrodes 20a and 20b is measured as an impedance Z. In FIG. 3, the current i flowing through a concrete portion is schematically shown by a two dot chain line, and the current is flowing through the surface of the reinforcing bar S is schematically shown by a chain line. In the case of the concrete structure S in which the reinforcing bar R is arranged, the current i flowing through the concrete portion and the current is passing through the surface of the reinforcing bar S are measured as impedance Z.

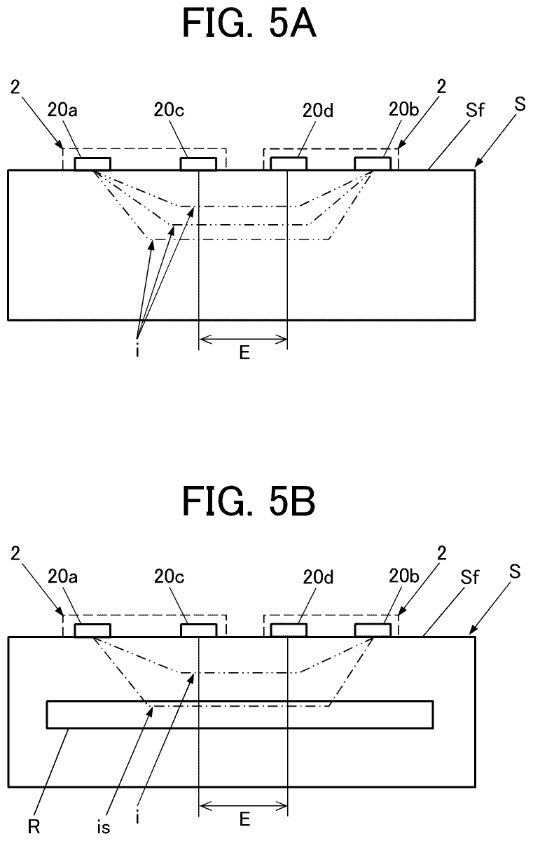

FIG. 4A is a graph illustrating an example of a relationship between the input alternating-current voltage and the response current, and FIG. 4B is a graph illustrating an example of a complex representation of the impedance Z.

When a phase difference of the response current i with respect to the input alternating-current voltage v applied to the electrodes 20a and the 20b is φ and an angular speed is w, the input alternating-current voltage v is obtained by the following Expression (1). The response current i is obtained by the following Expression (2). Furthermore, the impedance Z is obtained by the following Expression (3).

$$v ( t ) = {v}_{m} exp ( j ω t ) \qquad ( 1 )$$

$$i ( t ) = {i}_{m} exp ( j ω t + φ ) \qquad ( 2 )$$

$$Z ( ω ) = \frac{V ( ω )}{I ( ω )} = \vert Z \vert {e}^{j ∅} = \vert Z \vert cos ∅ + j \vert Z \vert sin ∅ = {Z}^{′} + {jZ}^{″} \qquad ( 3 )$$

In the impedance measurement method, impedance characteristics are analyzed from a Z′-Z″ plot of the impedance Z or frequency characteristics of |Z|, θ. The pair of electrodes 20c and 20d may be further provided on the inner side of the pair of electrodes 20a and 20b, and a current A and a voltage V in a measurement segment E may be independently measured.

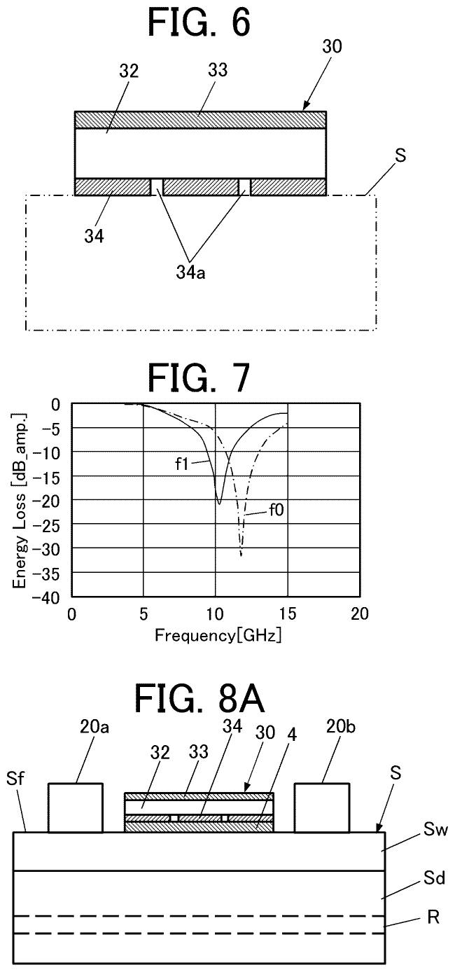

FIG. 5A is an explanatory diagram schematically illustrating a flow of a current in an impedance measurement method, and FIG. 5B is another explanatory diagram schematically illustrating the flow of the current in the impedance measurement method. FIG. 5A shows a case in which no reinforcing bar is arranged inside the concrete structure S. FIG. 5B shows a case in which the reinforcing bar R is arranged inside the concrete structure S.

When no reinforcing bar is arranged inside the structure S, the impedance of the measurement segment E receives influence by electrical resistance of the concrete. On the other hand, when the reinforcing bar R is disposed inside the structure S, the impedance of the measurement segment E is such that the current is passing through the surface of the reinforcing bar S is lower than the current i flowing through the concrete portion. In this way, according to the impedance measurement method, the presence or absence of the reinforcing bar R inside the structure S can be detected as a magnitude of the response current, that is, a magnitude of the impedance.

Furthermore, the impedance of the measurement segment E changes according to a chemical reaction such as rust or corrosion that occurs at the boundary between the concrete and the reinforcing bar R. Specifically, in addition to the magnitude of the response current (resistance value), the frequency response of the phase difference φ and the like change. Thus, according to the impedance measurement method, the presence or absence of the chemical reaction such as rust or corrosion occurring at the boundary between the concrete and the reinforcing bar R and the degree thereof can be detected as phase information of the impedance.

However, the impedance of the measurement segment E changes under the influence of the moisture being contained and the ion being contained in the concrete.

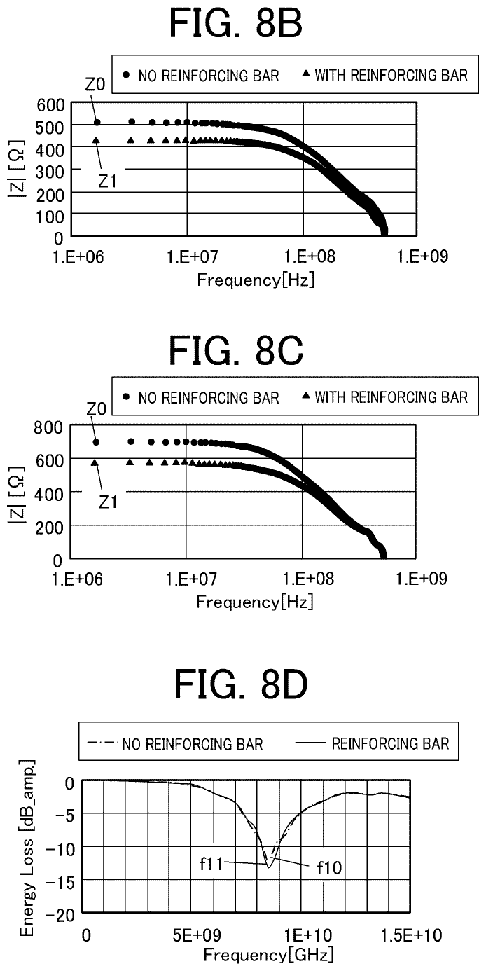

Therefore, according to the present embodiment, a resonance measurement method using microwaves is used in combination. FIG. 6 is an explanatory diagram showing an example of the resonant circuit used in the resonance measurement method. In the resonant circuit 30, a first surface of a substrate 32 is a microstrip surface, and a microstrip line 33 is provided on the microstrip surface. In the resonant circuit 30, the second surface of the substrate 32 serves as a ground surface thereinafter referred to as GND surface) and the resonant circuit 30 includes a resonator 34 in which a slit 34a is provided in the GND surface. The second sensor section 3 illustrated in FIG. 1A is provided on the side where the resonator 34 of the resonant circuit 30 faces the surface Sf of the structure S when the inspection apparatus 1A is installed on the surface Sf of the structure S.

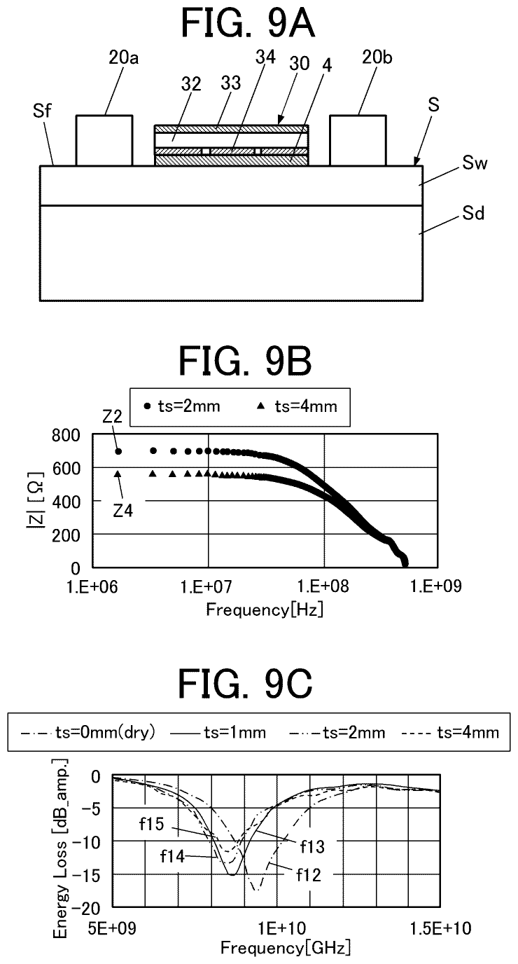

FIG. 7 is a graph showing an example of a change in the resonance frequency depending on the presence or absence of a derivative. In the resonance measurement method, an alternating current in a resonance band (GHz band) of the resonator 34 is passed through the resonator 34. When an alternating current flows through the resonator 34, an electric field is formed around the slit 34a of the resonator 34. Therefore, the resonance frequency of the resonator 34 is determined by an effective dielectric constant ε (eff) including the influence of a dielectric constant of a nearby object.

A resonance frequency f1 when a derivative is present close to the resonator 34 is indicated by a solid line in FIG. 7, and the resonance frequency f1 when no derivative is present is indicated by a chain line in FIG. 7. For example, the resonance frequency f1 in the presence of the derivative in the proximity to the resonator 34 changes relative to the resonance frequency f0 in the absence of the derivative. In this way, the presence or absence and the state of the object in the structure are detected by the change in the resonance frequency.

The concrete structure S is the derivative. The inspection apparatus 1A includes a resonant circuit 30 as the second sensor section 3. When the current in the resonance band flows through the resonator 34 with the inspection apparatus 1A installed on the surface Sf of the structure S, in the resonant circuit 30, the electric field is formed around the slit 34a of the resonator 34. The resonance frequency of the resonator 34 changes when the electric field formed around the slit 34a receives the influence by the structure S. The resonance frequency of the resonator 34 changes due to, for example, moisture being contained, ion being contained, and the like in the structure S. However, the strength of the electric field formed around the slit 34a of the resonator 34 becomes weaker as the distance from the resonator 34 increases.

Thus, the resonant circuit 30 is mainly influenced by the range in the vicinity of the surface Sf in the structure S, and the resonance frequency of the resonator 34 changes. On the other hand, the resonator 34 is less likely to be influenced by the range in which the reinforcing bar R separated from the surface Sf is arranged in the structure S. Therefore, the moisture being contained and the ion being contained in the concrete in the vicinity of the surface Sf of the structure S where the reinforcing bar R is not arranged can be extracted as an electrical signal by the resonance measurement method.

### <Verification of Impedance Measurement Method and Resonance Measurement Method>

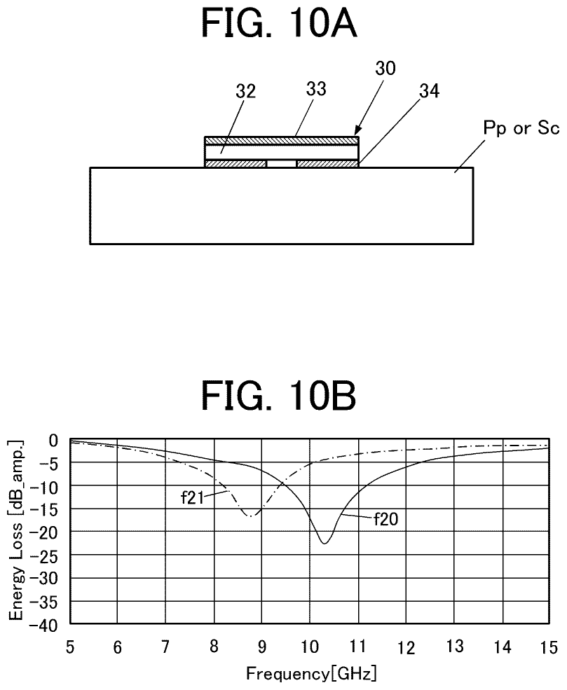

In the impedance measurement method and the resonance measurement method, first, the relationship between the presence or absence of the reinforcing bar and the impedance and the resonance frequency is verified. FIG. 8A is an explanatory diagram showing a configuration for measuring the relationship between the presence or absence of a reinforcing bar and the impedance and resonance frequency. FIG. 8B is a graph illustrating the presence or absence of the reinforcing bar and a measurement result of the impedance, and FIG. 8C is another graph illustrating the presence or absence of the reinforcing bar and the measurement result of the impedance. FIG. 8D is a graph showing the presence or absence of the reinforcing bar and the measurement result of the resonance frequency spectrum.

The pair of electrodes 20a and 20b for measuring the impedance were each made of a copper material, and the thicknesses were defined as 5 mm. In addition, 8 mm represents the length of the electrodes 20a and 20b in a direction in which they are aligned, 20 mm represents the length of the electrodes 20a and 20b in a direction orthogonal to the direction in which they are aligned, and 20 mm represents the interval between the electrodes 20a and 20b.

In the resonant circuit 30 whose resonance frequency is to be measured, the microstrip line 33 and the resonator 34 are each made of the copper material, and the thickness of each of the microstrip line 33 and the resonator 34 is set to a value so as to be referred to as a sheet shape. The substrate 32 is made to be 0.762 mm thick. The vertical and horizontal length of the resonant circuit 30 are each 10 mm, and the vertical and horizontal length of the resonator 34 are each 4 mm. In the resonant circuit 30, the 0.2 mm thick insulating member 4 is inserted between the resonator 34 and the structure S. The material of the insulating member 4 is polypropylene which will be described later.

The material used in the structure S is concrete, and a wet concrete material Sw containing moisture is provided on a dry concrete material Sd not containing moisture in order to make the influence of a moisture content constant. The thickness of the wet concrete material Sw is set as is (mm), and the thickness of the dry concrete material Sd is set as 20−ts (mm). As the structures for impedance measurement, two types of structures were used: the structure (structure S1) in which the wet concrete material Sw is 5 mm thick and the dry concrete material Sd is 15 mm thick, and the structure (structure S2) in which the wet concrete material Sw is 2 mm thick and the dry concrete material Sd is 18 mm thick. The structure S1 is used as the structure for measuring the resonance frequency. For each of the structures S1 and S2, the structure in which the reinforcing bar R is placed at a position 15 mm from the surface Sf of the wet concrete material Sw and the structure in which no reinforcing bar is placed are prepared.

The impedance was measured by the above-described impedance measurement method for the structure including no reinforcing bar and the structure including the reinforcing bar. An impedance Z0 measured under the above-described conditions without the reinforcing bar is indicated by a circle (solid circle) in FIG. 8B and FIG. 8C. An impedance Z1 in a case where the reinforcing bar is included is indicated with a triangle (filled triangle) in FIG. 8B and FIG. 8C.

Further, the resonance frequency is measured by the above-described resonance measurement method for the structure including no reinforcing bar and the structure including the reinforcing bar. A resonance frequency f10 in the case of not including the reinforcing bar measured under the above conditions is shown by a chain line in FIG. 8D. Further, a resonance frequency f11 when the reinforcing bar is included is shown by a solid line in FIG. 8D.

As illustrated m FIG. 8B (structure S1) and FIG. 8C (structure S2), it is found that there is a clear difference in the value of the impedance between the case where the reinforcing bar R is included at the predetermined depth from the surface Sf of the structure S and the case where the reinforcing bar R is not included. It is also found that the difference between the values of the impedance in the case where the reinforcing bar R is included and in the case where the reinforcing bar R is not included is not significantly influenced by the difference in the thickness ts of the wet concrete material Sw from the surface Sf of the structure S, that is, the difference in the moisture content. On the other hand, as shown in FIG. 8D, it is understood that there is no clear difference in the values of the resonance frequency between the case where the reinforcing bar R is included at a predetermined depth from the surface Sf of the structure S1 and the case where the reinforcing bar R is not included.

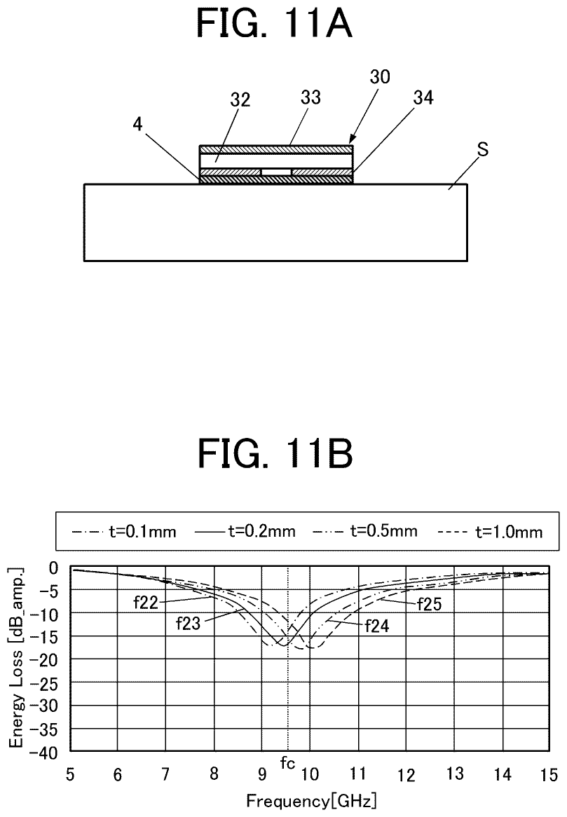

Next, the relationship between the moisture content of the structure and the impedance and the resonance frequency is verified. FIG. 9A is an explanatory diagram illustrating a configuration for measuring a relationship between the moisture content of the structure, and the impedance and resonance frequency FIG. 9B is a graph illustrating the measurement result of the moisture content of the structure and the impedance. FIG. 9C is a graph showing the measurement result of the moisture content of the structure and the resonance frequency spectrum.

The pair of electrodes 20a and 20b for measuring the impedance and the resonant circuit 30 for measuring the resonance frequency have the same configurations as those illustrated in FIG. 8A for verifying the presence or absence of the reinforcing bar.

The structure S does not include the reinforcing bar R, the material used in the structure S is concrete, and the wet concrete material Sw containing moisture is provided on the dry concrete material Sd not containing moisture. The thickness of the wet concrete material Sw is set as ts (mm), and the thickness of the dry concrete material Sd is set as 20−ts (mm).

The impedance is measured by the above-described impedance measurement method in a case where the thickness is of the wet concrete material Sw is set to 2 mm and in a case where the thickness ts is set to 4 mm. An impedance Z2 when the thickness ts of the wet concrete material Sw measured under the above-described conditions is 2 mm is indicated by the circle (filled circles) in FIG. 9B. Furthermore, the impedance Z4 in a case where the depth is of the wet concrete material Sw is 4 min is illustrated by the triangle (filled triangle) in FIG. 9B.

Furthermore, when the thickness ts of the wet concrete material Sw is set to 0 mm, 1 mm, 2 mm, and 4 mm, the resonance frequency is measured by the above-described resonance measurement method. A resonance frequency spectrum f12 when the thickness ts of the wet concrete material Sw measured under the above conditions is 0 mm is shown by the chain line in FIG. 9C. Further, a resonance frequency spectrum f13 when the thickness ts of the wet concrete material Sw is 1 mm is shown by the solid line in FIG. 9C. Further, a resonance frequency spectrum 114 when the thickness ts of the wet concrete material Sw is 2 mm is indicated by the two dot chain line in FIG. 9C. Further, a resonance frequency spectrum f15 when the thickness ts of the wet concrete material Sw is 4 mm is shown by a broken line in FIG. 9C.

The impedances Z2 and Z4 illustrated in FIG. 9B indicate the relationship in the case where no reinforcing bar is present and the thicknesses is of the wet concrete material Sw are 2 mm and 4 mm, respectively, which are similar to the relationship between the impedances Z1 and Z2 in the case where the reinforcing bar R is present and in the case where the reinforcing bar R is absent illustrated in FIG. 8C. Therefore, there is a possibility that the presence or absence of the reinforcing bar R and the magnitude of the moisture content of the structure S cannot be determined by the impedance measurement method.

On the other hand, as illustrated in FIG. 9C, it is found that the value of the resonance frequency has a clear difference depending on the thickness ts of the wet concrete material Sw from the surface Sf of the structure S, that is, the moisture content.

From the above verification, when the impedance measurement method and the resonance measurement method are used in combination, the presence or absence of the reinforcing bar R in the first range separated from the surface Sf in the structure S can be detected by the impedance measurement method. On the other hand, the moisture content and the ion content of the concrete in the vicinity of the surface Sf in the structure S can be detected by analyzing the change in the resonance frequency spectrum by the resonance measurement method. Combining these results makes it possible to distinguish between the presence or absence of the reinforcing bar R and the moisture content and the ion content of concrete. Therefore, the presence or absence of the reinforcing bar R, the presence or absence of the chemical reaction such as rust or corrosion occurring at the boundary between the concrete and the reinforcing bar R, and the degree of the chemical reaction can be extracted as the electrical signal.

### <Integrated Configuration Example of Inspection Apparatus>

The inspection apparatus 1A aligns installation positions of the first sensor section 2 and the second sensor section 3 with respect to the structure S in order to align the measurement positions in the impedance measurement method and the resonance measurement method.

Therefore, the inspection apparatus 1A has an integrated structure of the first sensor section 2 and the second sensor section 3. In the inspection apparatus 1A, the first sensor section 2 and the second sensor section 3 are mounted in, for example, the same housing 5 in the above-described predetermined arrangement. Furthermore, in the inspection apparatus 1A, the first sensor section 2 and the second sensor section 3 may be mounted on the same substrate (not illustrated). Further, in the inspection apparatus 1A, the first sensor section 2, the first acquisition section 21, the second sensor section 3, and the second acquisition section 31 may be mounted on the same housing 5 or the same substrate (not shown).

### <Installation Example of Insulating Member>

When the inspection apparatus 1A is installed on the surface Sf of the structure S, the resonator 34 of the second sensor section 3 needs to be fixed in proximity to the structure S. In the inspection apparatus 1A, when the structure S contains moisture, if the resonator 34 comes into direct contact with the surface Sf of the structure S, an electrical short circuit occurs, resulting in a malfunction. For this reason, in the inspection apparatus 1A, the resonator 34 needs to be fixed away from the surface Sf of the structure S. On the other hand, in the inspection apparatus 1A, the distance between the resonator 34 of the second sensor section 3 and the surface Sf of the structure S needs to be constant in order to stabilize the resonance characteristics and increase the stability of the measurement value.

Therefore, the inspection apparatus 1A includes the insulating member 4 between the resonator 34 of the second sensor section 3 and the surface Sf of the structure S. In the second sensor section 3, when the inspection apparatus 1A is installed on the surface Sf of the structure S, the insulating member 4 is inserted between the resonator 34 and the surface Sf of the structure S.

Thus, in the inspection apparatus 1A, the resonator 34 is not in direct contact with the surface Sf of the structure S. In the inspection apparatus 1A, the distance between the resonator 34 and the surface Sf of the structure S is defined by the thickness of the insulating member 4.

### <Verification of Insulating Member>

When the second measurement condition is the resonance measurement method, it is preferable that the insulating member 4 has a relative dielectric constant of 3 or less, an electrical resistivity of 10×E8 Ω·cm or more, the thickness of 1 μm or more and 200 μm or less, and a dielectric loss tangent of 0.1 or less.

When the second measurement condition is the resonance measurement method, the wave applied to the structure S by the second sensor section 3 is within the range from 1 GHz to 100 GHz. In this case, the insulating member 4 preferably has the thickness corresponding to 0.01% or more and 10% or less of a penetration depth of the wave applied to the structure S by the second sensor section 3.

The material and thickness of the insulating member 4 will be verified below. In the resonance measurement method, it is necessary to change the resonance frequency depending on the state of the structure S while suppressing the influence of the insulating member 4 on the electric field formed around the slit 34a of the resonator 34. Therefore, the insulating member 4 is desirably made of an insulating material having a small relative dielectric constant and a small dielectric loss tangent. When the material of the structure S is concrete, the relative dielectric constant is about 4 and the dielectric loss tangent is about 0.1. Therefore, polypropylene is considered to be an example of a desirable material for the insulating member 4. Polypropylene has the relative dielectric constant of about 2.2 and the dielectric loss tangent of about 0.0002, and the relative dielectric constant and the dielectric loss tangent are both smaller than those of concrete.

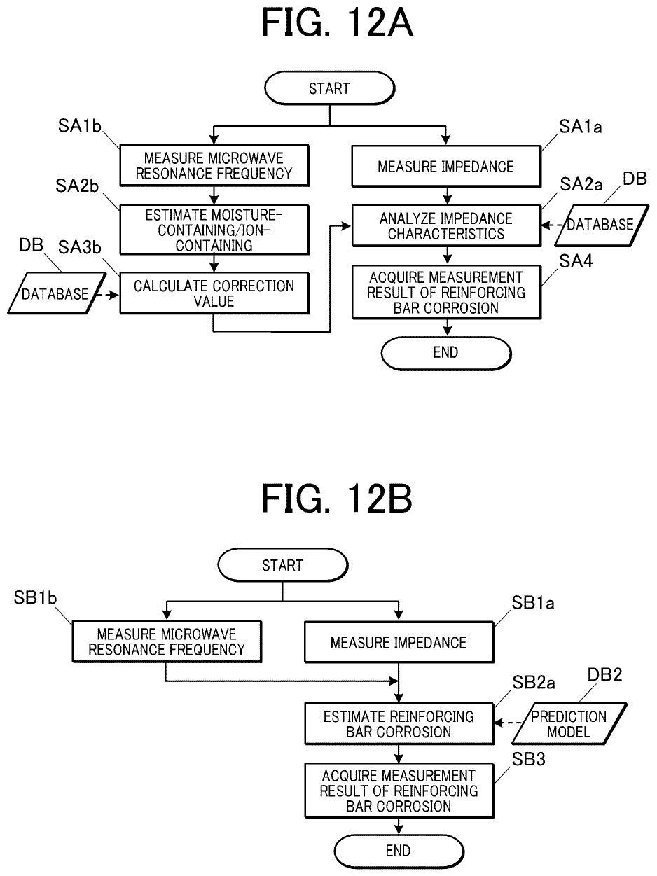

First, a difference in the resonance frequency between the polypropylene and the concrete in the above-described resonant circuit 30 is verified. FIG. 10A is an explanatory diagram showing a configuration for measuring the resonance frequency of the polypropylene and the concrete, and FIG. 11B is a graph showing the measurement result of the resonance frequency spectrum of the polypropylene and the concrete.

The above-described resonant circuit 30 is placed on each of the concrete material Sc and the polypropylene material Pp having a thickness of 5 mm, and a resonance frequency spectrum is measured. The resonant circuit 30 has the same configuration as that in which the presence or absence of the reinforcing bar described above is verified.

The resonance frequency of the concrete and the polypropylene as measurement targets is measured by the above-described resonance measurement method. The resonance frequency spectrum f20 of the polypropylene material Pp measured under the above condition is shown by the solid line in FIG. 10B, and the resonance frequency spectrum f21 of the concrete material Sc is shown by the chain line in FIG. 10B. As a result, it is found that there is the difference of about 1.5 GHz between the resonance frequency of the concrete material Sc and that of the polypropylene material Pp. This means that the polypropylene and the concrete can be distinguished when the predetermined resonance frequency is applied.

Next, in the configuration in which the insulating member 4 is inserted between the resonant circuit 30 and the structure S, the relationship between the thickness of the insulating member 4 and the resonance frequency will be verified. FIG. 11A is an explanatory diagram illustrating a configuration for measuring the relationship between the thicknesses of the insulating member and the resonance frequency, and FIG. 11B is a graph illustrating the measurement result of the thickness of the insulating member and the resonance frequency spectrum.

The material of the insulating member 4 is polypropylene. The structure S does not include the reinforcing bar R, the material used in the structure S is concrete, and the thickness of the structure S is 10 mm. The insulating member 4 having the thickness t (mm) is inserted between the resonant circuit 30 and the structure S, and the resonance frequency is measured. The resonant circuit 30 has the same configuration as that in which the presence or absence of the reinforcing bar described above is verified.

The resonance frequency spectrum f22 measured under the above condition when the insulating member 4 has the thickness t of 0.1 mm is indicated by the chain line in FIG. 11B. Further, the resonance frequency spectrum f23 when the insulating member 4 has the thickness of 0.2 mm is indicated by the solid line in FIG. 11B. Further, the resonance frequency spectrum f24 in the case where the insulating member 4 has the thickness t of 0.5 mm is indicated by the two dot chain line in FIG. 11B. The resonance frequency spectrum f25 in a case where the thickness t of the insulating member 4 is 1.0 mm is indicated by the broken line in FIG. 11B.

In FIG. 11B, fc represents an intermediate value of the resonance frequency when the thicknesses t of the insulating member 4 are set to 0.1 mm, 0.2 mm, 0.5 mm, and 1.0 mm. When the thickness t of the insulating member 4 exceeds 0.2 mm, the resonance frequency of the polypropylene become more dominant than the resonance frequency of the concrete when viewed from the intermediate value fc of the resonance frequency. Thus, it is understood that the thickness t of the insulating member 4 is desirably at least 0.2 mm or less in order to detect the state of the concrete.

Note that the insulating member 4 is desirably made of the insulating material having the relative dielectric constant and the dielectric loss tangent equivalent to those of polypropylene. Examples of such material include polyethylene terephthalate (PETF), low-density polyethylene, polyphenylene ether, and polytetrafluoroethylene (PTFE).

### <Operation Examples of Inspection Apparatus and Inspection System of Present Embodiment>

An example of an inspection method according to the present embodiment, which is an operation example of the inspection apparatus 1A and the inspection system 10, will be described.

In the inspection method of the present embodiment, the first sensor section applies the wave in the first frequency band to the structure S, and receives the transmitted wave and/or the reflected wave from the structure S. The wave of the second frequency band different from the first frequency band is applied to the structure S by the second sensor section, and the transmitted wave and/or the reflected wave from the structure S is received.

Then, data and/or a feature amount of different depth positions or depth ranges of the structure S are acquired using a different measurement condition depending on the frequency band with respect to the reception signal from each sensor.

In particular, the inspection method includes two or more measurement steps. A first measurement step acquires the data and/or the feature amount (first data or the like) with the first resolution with respect to a first range of the structure S in a first frequency band under a first measurement condition.

In addition, the second measurement step acquires the data and/or the feature amount (second data or the like) with a second resolution for a second range in a second frequency band under a second measurement condition. The second range is smaller than the first range, and the second resolution is higher than the first resolution.

When the number of measurement steps is two or more, the measurement condition different from the first measurement condition and the second measurement condition is used in the measurement step after the second measurement step. Then, the data and/or the feature amount is acquired while the range is reduced and the resolution is increased in the measurement step of the latter stage relative to the measurement step of the former stage. As described above, the measurement condition means the measurement method and/or the measurement parameter, and the measurement parameter includes the frequency band of the wave to be used.

Note that in the measurement step subsequent to the two or more measurement steps, the range and the resolution of the measurement may be determined on the basis of the data and/or the feature amount acquired in the preceding measurement step. In this case, the measurement range in the subsequent measurement step is made smaller than the measurement range in the preceding measurement step. However, a part of the measurement range is overlapped in the former measurement step and the latter measurement step. Furthermore, the resolution of the measurement in the subsequent measurement step is higher than the resolution of the measurement in the preceding measurement step.

An example of the inspection method in the case where the object to be inspected is the structure composed of the reinforcing bar and concrete as described above or the reinforcing bar and mortar is as follows. First, the electrical impedance from 10 Hz to the 10 MHz of the structure is acquired by the impedance measurement method. Further, the dielectric constant of the concrete or the mortar is acquired based on the resonance frequency from 1 GHz to the 10 GHz by the resonance measurement method.

The moisture content and/or the ion content of the concrete or mortar is estimated from the dielectric constant obtained as described above. The corrosion state of the reinforcing bar in the structure is evaluated by deriving the conductivity of the reinforcing bar from the electrical impedance by using the moisture content and/or the ion content as a correction value.

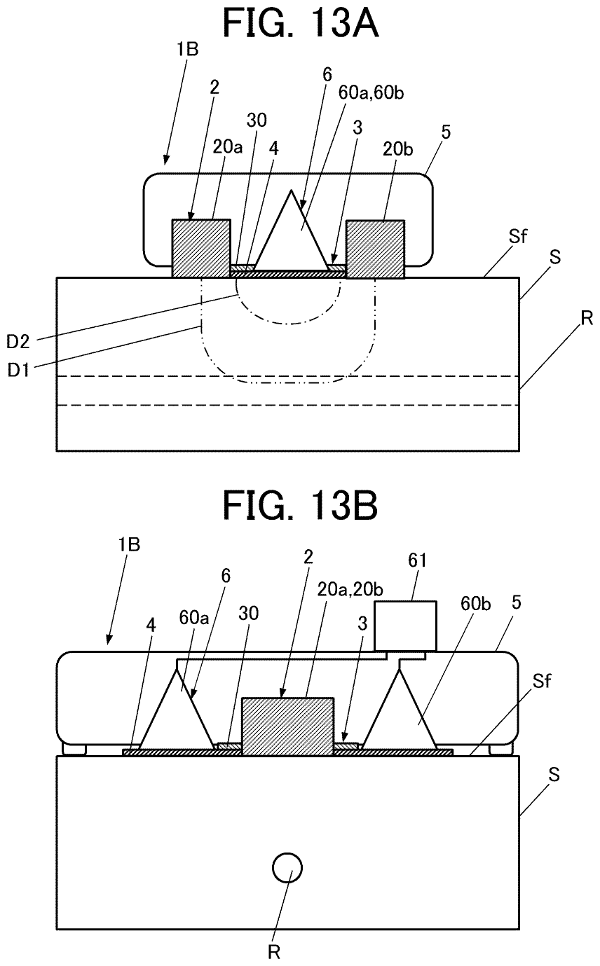

FIG. 12A is a flowchart illustrating an example of the operation of the inspection apparatus and the inspection system of the present embodiment. FIG. 12B is a flowchart illustrating another example of the operation of the inspection apparatus and the inspection system of the present embodiment. Furthermore. FIG. 12C is a flowchart illustrating a detailed example of the operation of the inspection apparatus and the inspection system of the present embodiment. Hereinafter, details of the inspection method using the inspection apparatus of the present embodiment will be described.

The inspection apparatus 1A shown in FIG. 1A and the like can perform measurement of the impedance by the impedance measurement method and measurement of the resonance frequency by the resonance measurement method at the same timing. Furthermore, the inspection apparatus 1A may measure the impedance and the resonance frequency at different timings.

The inspection apparatus 1A acquires the first data or the first feature amount with the first resolution from the first range of the structure S.

The inspection apparatus 1A acquires the second data or the second feature amount with the second resolution from the second range of the structure S. The second range is included in the first range and is the range narrower than the first range. The second resolution is the resolution higher than the first resolution.

The inspection system 10 corrects the first data or the first feature amount with the second data or the second feature amount as necessary, and acquires the measurement result indicating the state of the structure S.

As described above, the inspection apparatus 1A measures the impedance of the structure S with the first sensor section 2 and the first acquisition section 21. The inspection apparatus 1A measures the resonance frequency of the structure S with the second sensor section 3 and the second acquisition section 31.

Therefore, an example of an outline of the operation of the inspection apparatus 1A and the inspection system 10 will be described with reference to FIG. 12A and the like. In step SA1a of FIG. 12A, the inspection apparatus 1A measures the impedance in the first range of the structure S as the first data and the first feature amount. Also, in step SA1b, the inspection apparatus 1A measures the resonance frequency in the second range of the structure S as the second data and the second feature amount.

In step SA2b, the controller 12 of the inspection system 10 estimates the moisture content, the ion content, and the like from the resonance frequency in the second range of the structure S.

In step SA3b, the controller 12 calculates a correction amount used in the analysis of the impedance characteristics of the structure S on the basis of the moisture content, the ion content, and the like of the structure S.

In the inspection system 10, a database DB in which the moisture content, the ion content, and the like of the structure S are associated with the correction amount of the impedance characteristics is stored in the storage section 13. The controller 12 calculates the correction amount of the characteristic of the impedance based on the database DB.

In step SA2a, the controller 12 analyzes the characteristic of the impedance in the first range of the structure S. In addition, the controller 12 corrects the characteristic of the impedance using the correction amount based on the moisture content, the ion content, and the like in the second range of the structure S as necessary.

In the inspection system 10, the database DB in which the impedance characteristics of the structure S are associated with the presence or absence of the reinforcing bar m the structure S, the state of the reinforcing bar, and the like is stored in the storage section 13.

The controller 12 determines, based on the database DB, the presence or absence of the reinforcing bar, the state of the reinforcing bar, and the like from the impedance characteristics.

Then, in step SA4, the controller 12 acquires an inspection result of reinforcing bar corrosion, such as whether or not the reinforcing bar is corroded and the degree of corrosion, from the presence or absence of the reinforcing bar, the moisture content and the ion content of the structure, and the like.

In the above example, the moisture content, the ion content, and the like are estimated from the resonance frequency of the structure S. On the other hand, the measurement result indicating the state of the structure S may be directly acquired from the impedance characteristics of the structure S and the resonance frequency of the structure S.

In step SB1a of FIG. 1213, the inspection apparatus 1A measures and acquires the impedance in the first range of the structure S as the first feature amount. Also, in step SB1b, the inspection apparatus 1A measures and acquires the resonance frequency in the second range of the structure S as the second data and the second feature amount.

In step SB2a, the controller 12 of the inspection system 10 estimates the reinforcing bar corrosion from the characteristics of impedance in the first range of the structure S and the resonance frequency in the second range of the structure S.

In the inspection system 10, a prediction model DB2 for the reinforcing bar corrosion based on the impedance characteristics and the resonance frequency is stored in the storage section 13. The controller 12 estimates the reinforcing bar corrosion based on the prediction model DB2.

Then, in step SB3, the controller 12 acquires the measurement result of the reinforcing bar corrosion, such as whether or not the reinforcing bar is corroded and the degree of corrosion.

Next, a detailed example of the operation of the inspection apparatus 1A and the inspection system 10 will be described with reference to FIG. 12C and the like. In step SC1 of FIG. 12C, the inspection apparatus 1A is installed at a predetermined position on the surface Sf of the structure S.

In the inspection apparatus 1A, in step SC2a, a voltage from 10 Hz to 10 MHz is applied as the first frequency band to the pair of electrodes 20a and 20b of the first sensor section 2. Thus, the inspection apparatus 1A measures the impedance in the first range of the structure S as the first data and the first feature amount.

Furthermore, in step SC2b, the inspection apparatus 1A applies the voltage from 1 to 10 GHz as the second frequency band to the resonant circuit 30 of the second sensor section 3. Thus, the inspection apparatus 1A measures the resonance frequency in the second range of the structure S as the second data and the second feature amount.

In step SC3b, the controller 12 of the inspection system 10 analyzes the characteristics of the resonant frequency, such as the frequency, strength, width, and relative dielectric constant, from the resonance frequency spectrum in the second range of the structure S.

In step SC4b, the controller 12 estimates the moisture content, the ion content, and the like from the characteristics of the resonance frequency in the second range of the structure S.

In step SC5b, the controller 12 calculates the correction amount used in the analysis of the characteristics of the impedance of the structure S on the basis of the moisture content, the ion content, and the like of the structure S.

In the inspection system 10, the database DB in which the characteristics of the resonance frequency are associated with the moisture content, the ion content, and the like of the structure S is stored in the storage section 13. Further, in the inspection system 10, the database DB in which the moisture content, the ion content, and the like of the structure S are associated with the correction amount of the impedance characteristics is stored in the storage section 13. The controller 12 estimates the moisture content, the ion content, and the like based on the database DB (step SC4b). In addition, the controller 12 calculates the correction amount of the impedance characteristic based on the database DB (step SC5b).

In step SC3a, the controller 12 acquires the impedance characteristics from the Z′-Z″ plot of the impedance Z in the first range of the structure S, the frequency characteristics of the |Z|, θ, and the like.

In step SC4a, the controller 12 analyzes the characteristic of the impedance in the first range of the structure S. The controller 12 corrects the impedance characteristics using the correction amount based on the moisture content and the ion content in the second range of the structure S as necessary. In step SC5a, the controller 12 analyzes the characteristics of the impedance in the first range of the structure S to determine and quantify the corrosion of the reinforcing bar.

In the inspection system 10, the database DB in which the impedance characteristics of the structure S are associated with the presence or absence of the reinforcing bar in the structure S, the state of the reinforcing bar, and the like is stored in the storage section 13.

Based on the database DB, the controller 12 determines the presence or absence of the reinforcing bar, determines the reinforcing bar corrosion, and quantities the reinforcing bar corrosion from the impedance characteristics.

Next, in step SC6, the controller 12 acquires the inspection result of the reinforcing bar corrosion, such as whether the reinforcing bar is corroded and the degree of corrosion. The controller 12 outputs the inspection result of the reinforcing bar corrosion by the output section 14. The output section 14 outputs the inspection result of the reinforcing bar corrosion, for example, by display. Further, the controller 12 stores the inspection result of the reinforcing bar corrosion in the storage section 13. The controller 12 updates the database DB with the inspection result of the reinforcing bar corrosion, the data obtained by quantifying the reinforcing bar corrosion, and the like.

In step SC7, the controller 12 determines whether to continue the inspection. When the inspection is continued, the controller 12 outputs, with the output section 14 or the like, a notification for guiding the inspection apparatus 1A to be installed at the next inspection position or the like. When the inspection apparatus 1A is installed at the next inspection position, the inspection system 10 repeats the above-described measurement and inspection.

### <Another Example of Inspection Apparatus of Present Embodiment>

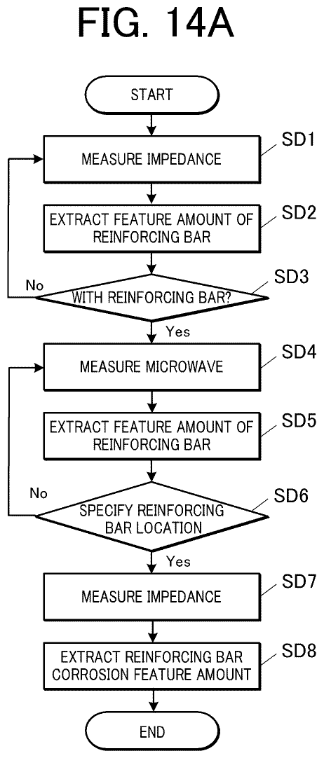

FIG. 13A is a front view illustrating another example of the inspection apparatus of the present embodiment, and FIG. 13B is a side view illustrating another example of the inspection apparatus of the present embodiment. Note that m the description of the inspection apparatus 1B, components equivalent to those of the inspection apparatus 1A are denoted by the same reference numerals.

The inspection apparatus 1B includes the first sensor section 2 that applies the waves in the first frequency band to the structure S and receives the waves transmitted through the structure S and/or the waves reflected by the structure S. Moreover, the inspection apparatus 1B includes the second sensor section 3 that applies the waves in the second frequency band to the structure S and receives the waves transmitted through the structure S and/or the waves reflected by the structure S. Further, the inspection apparatus 1B includes the third sensor section 6 that applies the waves in a third frequency band to the structure S and receives the waves transmitted through the structure S and/or the waves reflected by the structure S.

The configurations of the first sensor section 2 and the second sensor section 3 are equivalent to those described in FIG. 1A, FIG. 1B, and the like. In addition, although not illustrated, the first acquisition section provided corresponding to the first sensor section 2 is provided, and the second acquisition section provided corresponding to the second sensor section 3 is provided.

The third sensor section 6 includes an antenna 60a for transmission and an antenna 60b for reception of the waves in the third frequency band. The third sensor section 6 is arranged in a direction mutually orthogonal to the arrangement direction of the pair of electrodes 20a and 20b for performing impedance measurement, and the pair of antennas 60a and 60b are arranged at a predetermined interval.

The inspection apparatus 1B includes the insulating members 4 between the resonant circuit 30 and the surface Sf of the structure S and between the pair of antennas 60a and 60b and the surface Sf of the structure S. The insulating member 4 is provided between the pair of electrodes 20a and 20b, and extends in a direction orthogonal to the direction in which the pair of electrodes 20a and 20b are arranged. In the third sensor section 6, the pair of antennas 60a and 60b face the surface Sr of the structure S via the insulating member 4.

The third sensor section 6 applies, to the structure S waves (microwaves) having frequencies within the range from 1 GHz to 20 GHz, for example, as the third frequency band. The microwave is applied from a direction orthogonal to an extending direction of the reinforcing bar R.

The inspection apparatus 1B includes a third acquisition section 61 provided corresponding to the third sensor section 6. The third acquisition section 61 acquires data with a third resolution from a third range of the structure S using a third measurement condition with respect to the signal received from the third sensor section 6. Note that the third acquisition section 61 is not illustrated in the front view of FIG. 13A.

The third acquisition section 61 uses a measurement method with microwaves as the third measurement condition. A time-of-flight measurement method or a Doppler method is used as the measurement method by the microwave.

The inspection system 10 including the inspection apparatus 1B has the same configuration as that described with reference to FIG. 2. The controller 12 obtains the position of the reinforcing bar R in the structure S from the third data or the third feature amount acquired by the time-of-flight measurement method or the Doppler method.

Here, the time-of-flight measurement method is a method of calculating by converting the time it takes for the waves of a plurality of frequencies in the range from 1 GHz to 20 GHz, which are applied from the antenna, to be reflected off the structure S and to reach the antenna again to the distance related to the structure S by waveform analysis.

Furthermore, the Doppler method is a method of calculating the distance related to the structure S as follows. A single-frequency wave in the range from 1 GHz to 20 GHz, which is applied from the antenna that moves at a constant speed is Doppler-shilled and reflected by the structure S, and the wave arrives at the antenna again. Such wave is subjected to waveform analysis to calculate the above distance.

An example of the inspection method in the case where the object to be inspected is the structure composed of the reinforcing bar and the concrete or the reinforcing bar and the mortar by using the inspection apparatus of another example of the present embodiment is as follows. First, the electrical impedance from 10 Hz to 10 MHz of the structure is acquired by the impedance measurement method. Furthermore, the reception signal from 1 GHz to 20 GHz is acquired by the time-of-flight measurement method or the Doppler method.

From the electrical impedance obtained as described above, information on the position of the reinforcing bar in the structure and the moisture content and/or the ion content of the concrete or the mortar is derived. Then, the information on the reinforcing bar position is corrected using the reception signal from 1 GHz to 20 GHz. In addition or instead, the corrosion state of the reinforcing bar is evaluated.

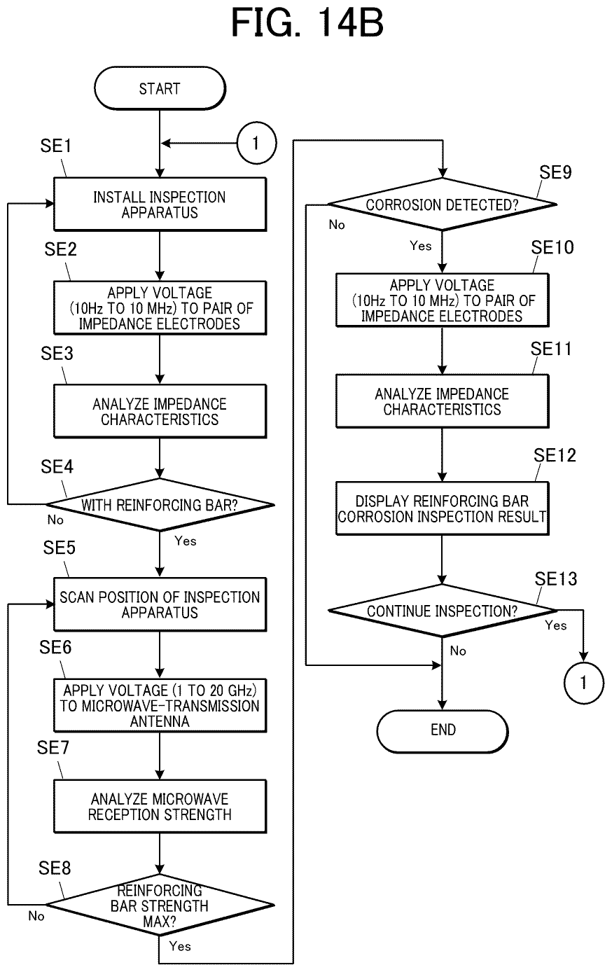

FIG. 14A is a flowchart showing an example of the operation of the inspection apparatus and the inspection system according to another example of the present embodiment. FIG. 14B is a flowchart illustrating a detailed example of the operation of the inspection apparatus and the inspection system of another example of the present embodiment. Hereinafter, details of the inspection method using the inspection apparatus of another example of the present embodiment will be described.

In step SD1 of FIG. 14A, the inspection apparatus 1A measures the impedance in the first range of the structure S as the first feature amount.

In step SD2, the controller 12 of the inspection system 10 analyzes the characteristics of the impedance in the first range of the structure S and extracts the feature amount of the reinforcing bar R. In step SD3, the controller 12 determines the presence or absence of the reinforcing bar R in the structure S from the feature amount of the reinforcing bar R.

Upon determination that the reinforcing bar R is present in the structure S, the controller 12 performs measurement by the time-of-flight measurement method or the Doppler method with microwaves in step SD4 In step SD5, the controller 12 analyzes a reception waveform of the microwave and extracts the feature amount related to the reinforcing bar R. In step SD6, the controller 12 specifies the position of the reinforcing bar R in the structure S from the feature amount related to the reinforcing bar R.

Upon identifying the position of the reinforcing bar R in the structure S, the controller 12 measures the impedance of the structure S in step SD7. In step SD8, the controller 12 analyzes the characteristics of the impedance of the structure S and extracts the feature amount of the reinforcing bar corrosion from a particular position.

When microwaves are applied from a predetermined direction with respect to the direction in which the reinforcing bar R extends, and measurement and analysis are performed by a time-of-flight measurement method or a Doppler method, the position of the reinforcing bar R can be specified. Thus, it is possible to determine whether the feature amount obtained by the impedance measurement method is the feature amount of the reinforcing bar corrosion or the feature amount due to moisture being contained or the like. Thus, the presence or absence and the degree of corrosion of the reinforcing bar can be inspected.

Note that the moisture content, the ion content, and the like of the structure S may be estimated by using the resonance measurement method in combination, and may be used for analysis and correction of the characteristics of the impedance of the structure S.

Next, a detailed example of the operation of the inspection apparatus 1B and the inspection system 10 will be described with reference to FIG. 14B and the like. In step SE1 of FIG. 14B, the inspection apparatus 1B is installed at a predetermined position on the surface Sf of the structure S.

In the inspection apparatus 1B, in step SE2, the voltage from 10 Hz to 10 MHz is applied as the first frequency band to the pair of electrodes 20a and 20b of the first sensor section 2. Thus, the inspection apparatus 1B measures the impedance in the first range of the structure S as the first data and the first feature amount.

In step SE3, the controller 12 of the inspection system 10 acquires impedance characteristics from the impedance in the first range of the structure S. Furthermore, the controller 12 analyzes the characteristics of the impedance and extracts the feature amount regarding the reinforcing bar R. In step SE4, the controller 12 determines the presence or absence of the reinforcing bar R in the structure S from the feature amount regarding the reinforcing bar R.

Upon determination that the reinforcing bar R is present in the structure S, in step SE5, the controller 12 scans the position of the inspection apparatus 1B and performs measurement by the time-of-flight measurement method or the Doppler method with microwaves. In the inspection apparatus 1B, in step SE6, the voltage from 1 GHz to 20 GHz as the third frequency band is applied to the pair of antennas 60a and 60b of the third sensor section 6.

The controller 12 analyzes reception strength of the microwaves in step SE7, and determines whether the reception strength is the maximum in step SE8. When the controller 12 determines that the reception strength of the microwaves is the maximum, the controller 12 determines whether or not corrosion of the reinforcing bar R is detected in step SE9.

When detecting the corrosion of the reinforcing bar R, the controller 12 measures the impedance at the position where the corrosion of the reinforcing bar R is detected. In the inspection apparatus 1B, in step SE10, the voltage from 10 Hz to 10 MHz is applied as the first frequency band to the pair of electrodes 20a and 20b of the first sensor section 2.

In step SE11, the controller 12 of the inspection system 10 acquires the impedance characteristics from the impedance of the structure S. Furthermore, the controller 12 analyzes the characteristics of the impedance and extracts the feature amount regarding the reinforcing bar R. In step SE12, the controller 12 acquires the inspection result of the reinforcing bar corrosion in the structure S from the feature amount regarding the reinforcing bar R. The controller 12 outputs the inspection result of the reinforcing bar corrosion by the output section 14. The output section 14 outputs the inspection result of the reinforcing bar corrosion, for example, by display. Further, the controller 12 stores the inspection result of the reinforcing bar corrosion in the storage section 13.

In step SE13, the controller 12 determines whether to continue the inspection. When the inspection is continued, the controller 12 outputs, with the output section 14 or the like, the notification for guiding the inspection apparatus 1B to be installed at the next inspection position or the like. When the inspection apparatus 1B is installed at the next inspection position, the inspection system 10 repeats the above-described measurement and inspection.

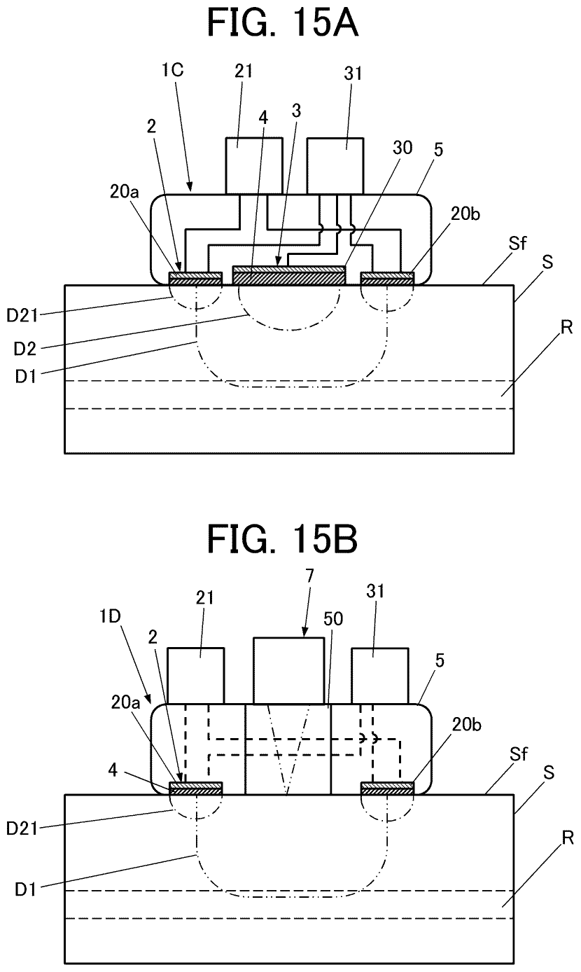

FIG. 15A is a front view showing still another example of the inspection apparatus of the present embodiment, and FIG. 15B is a front view showing still another example of the inspection apparatus of the present embodiment. Note that in the description of the inspection apparatuses 1C and 1D, components equivalent to those of the inspection apparatus 1A are denoted by the same reference numerals.

The inspection apparatus 1C includes the first sensor section 2 that applies the waves in the first frequency band to the structure S and receives the waves transmitted through the structure S and/or the waves reflected by the structure S. Moreover, the inspection apparatus 1C includes the second sensor section 3 that applies the waves in the second frequency band to the structure S and receives the waves transmitted through the structure S and/or the waves reflected by the structure S.

The first sensor section 2 includes the electrode 20a and the electrode 20b. When the inspection apparatus 1C is installed on the surface Sf of the structure S, the two electrodes 20a and 20b of the first sensor section 2 are in contact with the surface Sf of the structure S via the insulating member 4. In the first sensor section 2, the two electrodes 20a and 20b are arranged at the predetermined interval in the direction along the surface Sf of the structure S.

The second sensor section 3 includes the resonant circuit 30. In the second sensor section 3, the resonant circuit 30 is provided between the electrode 20a and the electrode 20b.

The inspection apparatus 1C realizes an integrated structure by sharing some of the constituent elements of the first sensor section 2 and the second sensor section 3. Therefore, the inspection apparatus 1C uses the electrode (solid electrode) constituting a resonator (not shown) of the resonant circuit 30 to form the pair of electrodes 20a and 20b Thus, the pair of electrodes 20a and 20b used in the impedance measurement method and the resonant circuit 30 used in the resonance measurement method can be formed as common electrodes. Therefore, the positional accuracy between the first sensor section 2 and the second sensor section 3 can be improved, and the measurement accuracy can be improved.

Note that by making the pair of electrodes 20a and 20b and the resonant circuit 30 into common electrodes, when the voltage is applied to the resonant circuit 30, the voltage is also applied to the pair of electrodes 20a and 20b. Thus, the pair of electrodes 20a and 20b function as the resonator, and the resonance frequency spectrum is acquired from the second depth range D21 corresponding to the pair of electrodes 20a and 20b.

In addition, by causing the pair of electrodes 20a and 20b to function as the resonator, the housing 5 can form an opening 50 between the pair of electrodes 20a and 20b, as shown in FIG. 15B. When the inspection apparatus 1D is installed on the surface Sf of the structure S, the surface Sf of the structure S is exposed to the opening 50 Thus, a fourth sensor section 7 may be provided that applies the waves in a fourth frequency band, such as infrared light, to the structure S from the opening 50 and receives the waves reflected by the structure S. The fourth sensor section 7 may be mounted on the housing 5 and integrated with the first sensor section 2 and the second sensor section 3. In addition, since the application position of the waves can be defined by the opening 50, the fourth sensor section 7 may be configured independently of the housing 5.

### <Application Example of Inspection Object>

In addition to the reinforcing bar-filled concrete structure, the object to be inspected may be soil, a composite material, a functional film, meat, a processed food, a cereal product such as rice and wheat, a new drug/tablet, and the like.

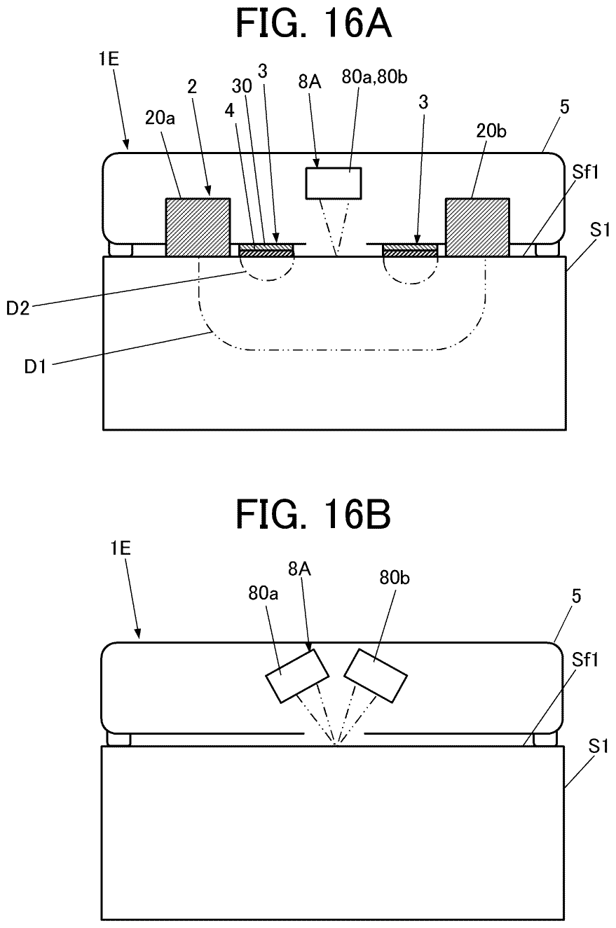

FIG. 16A is a front view illustrating an example of the inspection apparatus of the present embodiment applied to the soil, and FIG. 16B is a side view illustrating an example of the inspection apparatus of the present embodiment applied to the soil. In the inspection apparatus 1E, the same components as those of the inspection apparatus 1A and the like are denoted by the same reference numerals.

The inspection apparatus 1E includes the first sensor section 2 that applies the waves in the first frequency band to soil S1 and receives the waves transmitted through the soil S1 and/or the waves reflected by the soil S1. Moreover, the inspection apparatus 1E includes the second sensor section 3 that applies the waves in the second frequency band to the soil S1 and receives the waves transmitted through the soil S1 and/or the waves reflected by the soil S1. Further, the inspection apparatus 1E is provided with a fifth sensor section 8A that applies the waves in the fifth frequency band to the soil S1 and receives the waves transmitted through the soil S1 and/or the waves reflected by the soil S1.

The first sensor section 2 includes the electrode 20a and the electrode 20b. When the inspection apparatus 1 is installed on a surface Sf1 of the soil S1, the two electrodes 20a and 20b of the first sensor section 2 are in contact with the surface Sf1 of the soil S1 In the first sensor section 2, the two electrodes 20a and 20b are arranged at the predetermined interval in a direction along the surface Sf1 of the soil S1.

The second sensor section 3 includes the resonant circuit 30. In the second sensor section 3, the resonant circuit 30 is provided between the electrode 20a and the electrode 20b.

The fifth sensor section 8A includes a light emitting section 80a that irradiates the soil S1 with infrared light as the waves in the fifth frequency band. The fifth sensor section 8A includes a light receiving section 80b for receiving the infrared light reflected by the surface Sf1 of the soil S1.

When the inspection target is the soil, it is desirable that the moisture content and the ion content of the soil can be measured. Therefore, combined use of the measurement of the impedance and the measurement of the resonance frequency improves the accuracy m the measurement of the moisture-containing and the ion-containing material. In addition, in combination with measurement by visible light or infrared light, application to quality control of the state of a surface of the soil or harvest can also be expected.

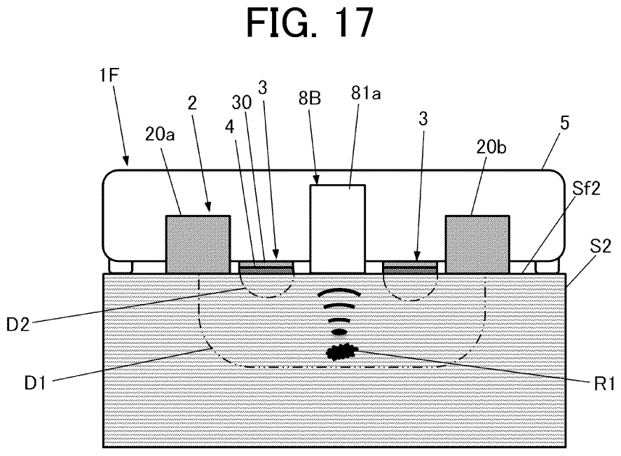

FIG. 17 is a front view illustrating an example of the inspection apparatus of the present embodiment applied to the composite material or the functional film. In the inspection apparatus 1F, the same components as those of the inspection apparatus 1A and the like are denoted by the same reference numerals. Hereinafter, the composite material in which a plurality of types of materials are multilayered will be described as an example.

The inspection apparatus 1F includes the first sensor section 2 that applies the waves in the first frequency band to a composite material S2 and receives the waves transmitted through the composite material S2 and/or the waves reflected by the composite material S2. In addition, the inspection apparatus 1F includes the second sensor section 3 that applies the waves in the second frequency band to the composite material S2 and receives the waves transmitted through the composite material S2 and/or the waves reflected by the composite material S2. Further, the inspection apparatus 1F is provided with a sixth sensor section 8B that applies the waves in a sixth frequency band to the composite material S2 and receives the waves transmitted through the composite material S2 and/or the waves reflected by the composite material S2.

The first sensor section 2 includes the electrode 20a and the electrode 20b. When the inspection apparatus 1F is installed on a surface Sf2 of the composite material S2, the two electrodes 20a and 20b of the first sensor section 2 are in contact with the surface Sf2 of the composite material S2. In the first sensor section 2, the two electrodes 20a and 20b are arranged at a predetermined interval in a direction along the surface Sf2 of the composite material S2.

The second sensor section 3 includes a resonant circuit 30. In the second sensor section 3, the resonant circuit 30 is provided between the electrode 20a and the electrode 20b.

The sixth sensor section 8B includes an ultrasonic probe 81a that irradiates the composite material S2 with ultrasound as the waves in the sixth frequency band.

When the inspection target is the composite material, it is desirable to be able to measure and detect a filler content percentage, a filler distribution and orientation state, a resin dielectric constant, a derivative loss, a foreign substance, a defect, peeling, and the like. Therefore, combined use of the impedance measurement and the resonance frequency measurement makes it possible to perform analysis in which structural information on the vicinity of the outermost surface and the inside of the composite material is separated. In addition, by combining with observation of an ultrasound image or X-ray image, it is possible to develop precise analysis in which the influence of interlayer peeling or the foreign substance R2 is taken into consideration.

In a case where the inspection target is a functional film, it is desirable to be able to measure and detect the filler content percentage, the filler distribution/orientation state, the resin dielectric constant/derivative loss, mechanical physical properties, chemical physical properties, a foreign substance, a defect, and the like. Therefore, by using the measurement of the impedance and the measurement of the resonance frequency in combination, the physical property distribution of the functional film can be three dimensionally grasped, and the conductivity and the derivative property can be precisely measured. In addition, by combining with the observation of the ultrasound image or the X-ray image, a plurality of physical property evaluations and managements required for the functional film can be easily performed.

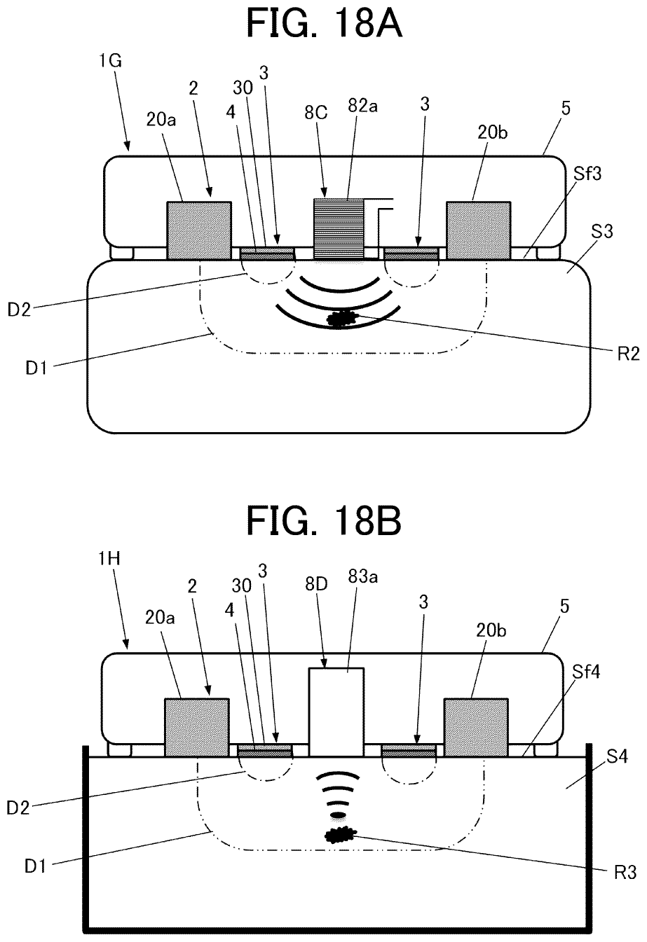

FIG. 18A is a front view illustrating an example of the inspection apparatus of the present embodiment applied to meat, and FIG. 18B is a front view illustrating an example of the inspection apparatus of the present embodiment applied to processed foods. Note that in the description of the inspection apparatus 1G and 1H, components equivalent to those of the inspection apparatus 1A and the like are denoted by the same reference numerals.

The inspection apparatus 1G is provided with the first sensor section 2 for applying the waves of the first frequency band to meat S3 and receiving the waves transmitted through the meat S3 and/or the waves reflected by the meat S3. Moreover, the inspection apparatus 1G is provided with the second sensor section 3 for applying the waves of the second frequency band to the meat S3 and receiving the waves transmitted through the meat S3 and/or the waves reflected by the meat S3. Furthermore, the inspection apparatus 1G is provided with a seventh sensor section 8C for applying the waves of a seventh frequency band to the meat S3 and receiving the waves transmitted through the meat S3 and/or the waves reflected by the meat S3.

The first sensor section 2 includes the electrode 20a and the electrode 20b. When the inspection apparatus 10 is installed on a surface Sf3 of the meat S3, the two electrodes 20a and 20b of the first sensor section 2 are in contact with the surface Sf3 of the meat S3. In the first sensor section 2, the two electrodes 20a and 20b are arranged at the predetermined interval in a direction along the surface Sf3 of the meat S3.

The second sensor section 3 includes the resonant circuit 30 In the second sensor section 3, the resonant circuit 30 is provided between the electrode 20a and the electrode 20b.

The seventh sensor section 8C includes a magnetic coil 82a that detects magnetism as the waves in the seventh frequency band.

The inspection apparatus 1H is provided with the first sensor section 2 for applying the waves of the first frequency band to processed food S4 and receiving the waves transmitted through the processed food S4 and/or the waves reflected by the processed food S4. Moreover, the inspection apparatus 1H is provided with the second sensor section 3 for applying the waves of the second frequency band to the processed food S4 and receiving the waves transmitted through the processed food S4 and/or the waves reflected by the processed food S4. Furthermore, the inspection apparatus 1H is provided with an eight sensor section 8D for applying the waves of an eighth frequency band to the processed food S4 and receiving the waves transmitted through the processed food S4 and/or the waves reflected by the processed food S4.

The first sensor section 2 includes the electrode 20a and the electrode 20b. When the inspection apparatus 1H is installed on a surface Sf4 of the processed food S4, the two electrodes 20a and 20b of the first sensor section 2 are in contact with the surface Sf4 of the processed food S4. In the first sensor section 2, the two electrodes 20a and 20b are arranged at the predetermined interval in a direction along the surface Sf4 of the processed food S4.

The second sensor section 3 includes the resonant circuit 30 In the second sensor section 3, the resonant circuit 30 is provided between the electrode 20a and the electrode 20b.

The eighth sensor section 8D includes an ultrasonic probe 83a that irradiates the processed food S4 with the ultrasound as waves in the eighth frequency band.

In a case where the inspection target is the meat, it is desirable that moisture percentage, protein, marbling, fat, bone, and a foreign substance such as a metal piece can be measured and detected. Therefore, combined use of the measurement of the impedance and the measurement of the resonance frequency can be utilized for quality evaluation (distribution and quality of moisture, protein, and fat) of the entire meat. Furthermore, by combining with ultrasound observation and a magnetic sensor, it can be used for evaluation of uniformity and detection of a foreign substance R3 such as a small bone and the metal piece.

In a case where the inspection target is the processed food, it is desirable that the moisture percentage, the protein, the fat, the bone, and the foreign substance such as the metal piece can be measured and detected. Therefore, combined use of the measurement of the impedance and the measurement of the resonance frequency can be utilized for quality evaluation such as material uniformity and the difference in moisture between the surface and the inside with respect to a mixture of different materials such as a hamburger patty. Moreover, by combining with the ultrasound observation and the magnetic sensor, it can be used for the evaluation of uniformity and the detection of the foreign substance such as the small bone and the metal piece.

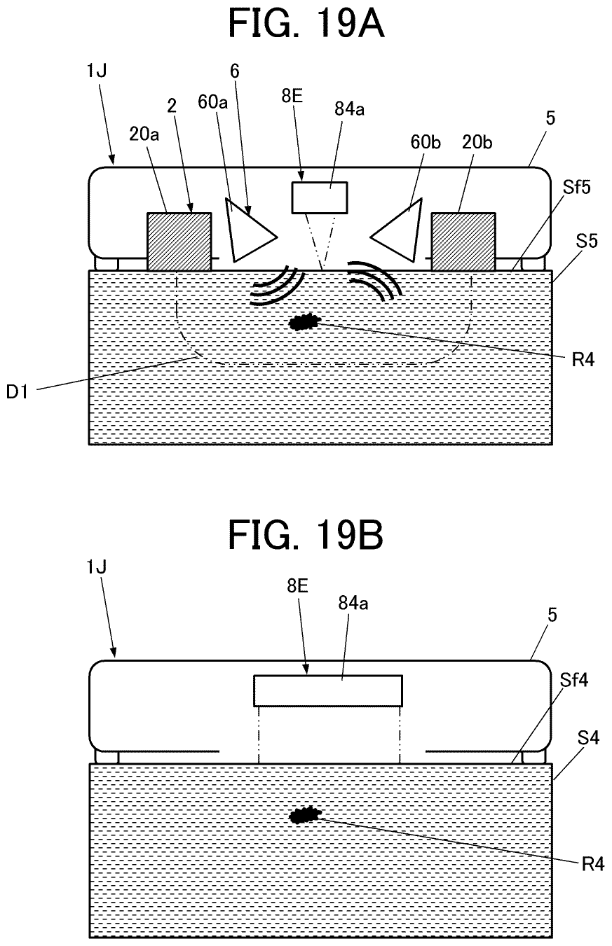

FIG. 19A is a front view illustrating an example of the inspection apparatus of the present embodiment applied to the cereal products such as rice and barley, and FIG. 19B is a side view illustrating an example of the inspection apparatus of the present embodiment applied to the cereal products. In the inspection apparatus 1J, the same components as those of the inspection apparatus 1A and the like are denoted by the same reference numerals. The cereal product to be inspected is an aggregate put in a bag or the like.

The inspection apparatus 1J is provided with the first sensor section 2 for applying the waves of the first frequency band to a cereal product S5 and receiving the waves transmitted through the cereal product S5 and/or the waves reflected by the cereal product S5. Further, the inspection apparatus 1J is provided with the third sensor section 6 for applying the waves of the third frequency band to the cereal product S5 and receiving the waves transmitted through the cereal product S5 and/or the waves reflected by the cereal product S5. Further, the inspection apparatus 1J is provided with a ninth sensor section 8E for applying the waves of a ninth frequency band to the cereal product S5 and receiving the waves transmitted through the cereal product S5 and/or the waves reflected by the cereal product S5.

The first sensor section 2 includes the electrode 20a and the electrode 20b. When the inspection apparatus 1J is installed on a surface Sf5 of the cereal product S5, the two electrodes 20a and 20b of the first sensor section 2 are in contact with the surface S15 of the cereal product S5. In the first sensor section 2, the two electrodes 20a and 20b are arranged at the predetermined interval m a direction along the surface Sf3 of the cereal product S5.

The third sensor section 6 includes the antenna 60a and the antenna 60b. The third sensor section 6 is arranged in a direction orthogonal to the direction in which the pair of electrodes 20a and 20b for performing the impedance measurement are aligned, and the pair of antennas 60a and 60b are arranged at a predetermined interval.

The ninth sensor section 8E includes a light receiving/light emitting section 84a that irradiates the cereal product S5 with infrared light as the waves of the ninth frequency band and receives the infrared light reflected by the surface Sf5 of the cereal product S5.

When the inspection target is rice, it is desirable to be able to measure and detect a size and density of rice grains, the foreign substance R4, and the like. Therefore, it can be expected that the measurement of the impedance, the measurement of the microwaves, and the measurement of the infrared light are used m combination, and the feature amount caused by the moisture is used to inspect the quality of the contained moisture or the rice. Further, since this method is simpler than the conventional inspection method, it can be easily incorporated into an inspection line.

In a case where the inspection target is a new drug/tablet, it is desirable that a chemical species, a foreign substance, a moisture residual, and the like can be measured and detected. Therefore, by using the measurement of the impedance, the microwave measurement, and the infrared light measurement in combination, information on the chemical species or additives relating to drug efficacy and information on residual products such as moisture or foreign substance are separated, and thus it is possible to perform highly accurate quality evaluation.

An example of the inspection method applied to the above-described various inspection objects is as follows. In a first measurement step of the two or more measurement steps, the first data or feature amount is acquired from the first range under the first measurement condition. The first measurement condition is the impedance measurement method or the measurement method using the microwaves.

In the second measurement step, the second data or feature amount is acquired from the second range under the second measurement condition. The second measurement condition is the measurement method using the microwaves or the measurement method using electromagnetic waves when the second range is shallower than the first range or is a shallow part in the first range. Moreover, the second measurement condition is any of the impedance measurement method, the measurement method using the ultrasound or an acoustic wave, and the measurement method using a magnetic field when the second range is deeper than the first range or is a deep part in the first range.

The feature amount acquired in the first measurement step is at least any of electrical frequency characteristics, mechanical physical properties, chemical physical properties, contained moisture, contained ion, and oil.

When the second range is shallower than the first range or is the shallow part in the first range, the feature amount acquired in the second measurement step is at least any of structural information of a buried object, the tiller, the foreign substance, and the defect. In addition, when the second range is deeper than and has a narrower range than the first range, the feature amount acquired in the second measurement step is at least any of the structural information of the buried object, the filler, the foreign substance, and the defect. Further, when the second range is deeper than and has a wider range than the first range, the feature amount acquired in the second measurement step is at least the electrical frequency characteristics, the mechanical physical properties, the chemical physical properties, the contained moisture, the contained ion, and the oil.

Then, the inspection result of the object is acquired by analyzing the feature amount acquired in the first measurement step and the feature amount acquired in the second measurement step.

### INDUSTRIAL APPLICABILITY

The present invention can be used for an inspection apparatus and an inspection method for inspection of an inside of a structure nondestructively.

### REFERENCE SIGNS LIST

1A . . . inspection apparatus, 2 . . . first sensor section, 20a, 20b . . . electrodes, 21 . . . first acquisition section, 3 . . . second sensor section, 30 . . . resonant circuit, 31 . . . second acquisition section, 4 . . . insulating member, 5 . . . housing, 10 . . . inspection system. 11 . . . analysis apparatus, 12 . . . controller

1. An inspection apparatus comprising:
a plurality of sensors that apply waves in different frequency bands to a target and that receive a transmitted wave and/or a reflected wave from the target; and
a plurality of acquirers that are provided corresponding to the plurality of sensors and that acquire data and/or a feature amount at different depth positions or depth ranges of the target using different measurement conditions,
wherein the plurality of sensors or the plurality of sensors and the plurality of acquirers are formed in an integrated structure.

2. The inspection apparatus according to claim 1, wherein one of the measurement conditions is that the frequency band is within a range from 1 Hz to 100 MHz.

3. The inspection apparatus according to claim 2, wherein,
one of the measurement conditions is an impedance measurement method, and
one of the sensors includes two or more electrodes disposed on one of a plurality of surfaces constituting an outer surface of the target, and acquires the data and/or the feature amount of the target between a pair of the electrodes.

4. The inspection apparatus according to claim 3, wherein another one of the measurement conditions is that the frequency band is within a range from 1 GHz to 100 GHz.

5. The inspection apparatus according to claim 4, wherein another one of the measurement conditions is a measurement method using microwaves, and any of a resonance measurement method, a time-of-flight measurement method, and a Doppler method is used.

6. The inspection apparatus according to claim 5, further comprising at least one resonant circuit including resonance frequencies in a frequency band from 1 GHz to 10 GHz in another one of the sensors and/or another one of the acquirers in the resonance measurement method.

7. The inspection apparatus according to claim 5, further comprising an interference reducer between the plurality of sensors and/or adjacent to the plurality of sensors, wherein the interference reducer suppresses interference among waves applied by the plurality of sensors.

8. The inspection apparatus according to claim 7, wherein when another one of the measurement conditions is a resonance measurement method, the interference reducer is formed by disposing an insulating member having a relative dielectric constant of 3 or less, an electrical resistivity of 10×E8 Ω·cm or more, and a thickness of 1 μm or more and 200 μm or less between another one of the sensors and the target.

9. The inspection apparatus according to claim 7, wherein when another one of the measurement conditions is a resonance measurement method, the interference reducer is formed by disposing an insulating member having a thickness equivalent to 0.01% or more and 10% or less of a penetration depth of a wave applied to the target by another one of the sensors between another one of the sensors and the target.

10. The inspection apparatus according to claim 1, wherein, in the integration structure, a part of a constituent element of the plurality of the sensors is common.

11. The inspection apparatus according to claim 5, wherein, in the integration structure, another one of the sensors includes an antenna for transmitting the microwave and an antenna for receiving the microwave, and an arrangement direction of a pair of the antennas is orthogonal to an arrangement direction of the pair of the electrodes.

12. The inspection apparatus according to claim 6, wherein, in the integration structure, the resonant circuit is disposed between the pair of the electrodes.

13. An inspection method comprising:
by using a plurality of sensors, applying waves in different frequency bands to a target and receiving a transmitted wave and/or a reflected wave from the target; and
with respect to reception signals from the plurality of sensors, acquiring data and/or a feature amount at different depth positions or depth ranges of the target using different measurement conditions.

14. The inspection method according to claim 13,
further comprising 2 or more measurement steps,
wherein,
in a first measurement step,
the data and/or the feature amount is acquired with a first resolution for a first range of the target under a first measurement condition,
in a second measurement step,
the data and/or the feature amount is acquired with a second resolution higher than the first resolution with respect to a second range smaller than the first range under a second measurement condition,
in a measurement step subsequent to the second measurement step,
under a measurement condition different from the first measurement condition and the second measurement condition, the data and/or the feature amount is acquired in a smaller range and with a higher resolution in a latter measurement step than in a former measurement step.

15. The inspection method according to claim 14, wherein, in the measurement step subsequent to the two or more measurement steps, the range and the resolution of a measurement is determined based on the data and/or the feature amount acquired in the preceding measurement step.

16. The inspection method according to claim 14,
wherein,
in the first measurement step,
when the first range covers a whole or a wide range of the target, the first measurement condition uses a frequency band of 1 kHz or more and 100 GHz or less,
in the second measurement step,
when the second range is a shallower portion than the first range or a shallow portion in the first range, the second measurement condition uses a frequency band equal to or higher than 1 GHz, and
when the second range is a deeper portion than the first range or a deep portion in the first range, the second measurement condition uses a frequency band of 1 Hz or more and 100 GHz or less.

17. The inspection method according to claim 16, wherein,
in the first measurement step,
the first measurement condition is an impedance measurement method or a measurement method using microwaves,
in the second measurement step,
the second measurement condition is the measurement method using the microwaves or the measurement method using electromagnetic waves when the second range is the shallower portion than the first range or is the shallow portion in the first range, and
when the second range is the deeper portion than the first range or is the deep portion in the first range, the measurement method is any of the impedance measurement method, the measurement method using an ultrasound or an acoustic wave, and the measurement method using the magnetic field.

18. The inspection method according to claim 14, wherein,
in the first measurement step,
the feature amount acquired in the first measurement step is at least any of electrical frequency characteristics, mechanical physical properties, chemical physical properties, contained moisture, contained ion, and oil,
in the second measurement step,
when the second range is a shallower portion than the first range or is a shallow portion in the first range, or is a further deeper portion and a narrow range, the feature amount acquired in the second measurement step is at least any of structural information of a buried object, a filler, a foreign substance, and a defect, and
when the second range is a deeper portion than and has a wider range than the first range, the feature amount acquired in the second measurement step is at least the electrical frequency characteristics, the mechanical physical properties, the chemical physical properties, the contained moisture, the contained ion, and the oil.

19. An inspection method comprising:
when an inspection target is a structure formed of a reinforcing bar and concrete or a reinforcing bar and mortar,
acquiring by an impedance measurement method electrical impedance from 10 Hz to 10 MHz;
acquiring by a resonance measurement method dielectric constant of the concrete or the mortar based on a resonance frequency from 1 GHz to 10 GHz; and
estimating a moisture content and/or an ion content of the concrete or the mortar from the dielectric constant, and evaluating a corrosion state of the reinforcing bar in the structure by deriving conductivity of the reinforcing bar from the electrical impedance with a moisture content and/or an ion content as a correction value.

20. (canceled)
